(19) United States
(12) Patent Application Publication
(10) Pub. No.: US 2023/0215892 A1
(43) Pub. Date: Jul. 6, 2023

(54) IMAGE SENSOR, CAMERA MODULE INCLUDING THE IMAGE SENSOR, ELECTRONIC DEVICE INCLUDING THE CAMERA MODULE, AND METHOD OF MANUFACTURING THE IMAGE SENSOR

(71) Applicant: SAMSUNG ELECTRONICS CO., LTD., Suwon-si (KR)

(72) Inventors: Kooktae KIM, Hwaseong-si (KR); Jingyun KIM, Jeju-do (KR); Jonghyeon NOH, Hwaseong-si (KR); Miseon PARK, Hwaseong-si (KR); Jaewoong LEE, Yongin-si (KR)

(73) Assignee: SAMSUNG ELECTRONICS CO., LTD., Suwon-si (KR)

(21) Appl. No.: 18/086,257

(22) Filed: Dec. 21, 2022

(30) Foreign Application Priority Data
Jan. 6, 2022 (KR) 10-2022-0001947

(51) Int. Cl. H01L 27/146

(52) U.S. Cl. CPC H01L 27/1463; H01L 27/14645; H01L 27/14621; H01L 27/14627; H01L 27/14683; G02B 5/201

(57) ABSTRACT

An image sensor includes a pixel division structure, a light sensing element, a color filter array layer and a microlens. The pixel division structure extends through a substrate in a vertical direction, and defines unit pixel regions. The light sensing element is in each unit pixel region. The color filter array layer including color filters is on the substrate. The microlens is on the color filter array layer. The pixel division structure includes a core and a lateral pattern structure on a sidewall thereof. The core includes a first filling pattern including polysilicon doped with impurities at a first concentration and a second filling pattern in a space formed by the first filling pattern. A sidewall of the second filling pattern is covered by the first filling pattern, and the second filling pattern includes polysilicon doped with impurities at a second concentration different from the first concentration.

### CROSS-REFERENCE TO RELATED APPLICATION

This application is based on and claims priority from Korean Patent Application No. 10-2022-0001947, filed on Jan. 6, 2022 in the Korean Intellectual Property Office (KIPO), the disclosure of which is incorporated herein in its entirety by reference.

### BACKGROUND

### 1. Field

Example embodiments relate to an image sensor, a camera module including the image sensor, an electronic device including the camera module, and a method of manufacturing the image sensor.

### 2. Description of Related Art

When a pixel division structure for dividing pixels is formed in an image sensor, a trench is formed in a substrate, a lateral pattern structure is formed on a sidewall of the trench, and a polysilicon layer is formed in the trench. However, a seam in the polysilicon layer may be enlarged to be a void due to silicon migration during a sequent thermal treatment. Thus, even though a negative bias is applied to the pixel division structure, the void may cause a dark current generated at a boundary between the pixel division structure and a light sensing element not to decrease.

### SUMMARY

Example embodiments provide an image sensor having improved characteristics.

Example embodiments provide a camera module including the image sensor having improved characteristics.

Example embodiments provide an electronic device including the camera module having improved characteristics.

Example embodiments provide a method of manufacturing an image sensor having improved characteristics.

In accordance with an aspect of the disclosure, an image sensor includes a pixel division structure extending through a substrate in a vertical direction, the vertical direction being substantially perpendicular to an upper surface of the substrate, the pixel division structure defining unit pixel regions in which unit pixels are respectively formed; a light sensing element in each of the unit pixel regions; a color filter array layer on the substrate, the color filter array layer comprising color filters; and a microlens on the color filter array layer, wherein the pixel division structure includes a core; and a lateral pattern structure on a sidewall of the core, and wherein the core includes a first filling pattern including polysilicon doped with p-type impurities or n-type impurities at a first impurity concentration; and a second filling pattern in a space formed by the first filling pattern, a sidewall of the second filling pattern being covered by the first filling pattern, and the second filling pattern comprising polysilicon doped with p-type impurities or n-type impurities at a second impurity concentration different from the first impurity concentration.

In accordance with an aspect of the disclosure, an image sensor includes a pixel division structure extending through a substrate in a vertical direction, the vertical direction being substantially perpendicular to an upper surface of the substrate, the pixel division structure defining unit pixel regions in which unit pixels are respectively formed; a light sensing element in each of the unit pixel regions; a color filter array layer on the substrate, the color filter array layer comprising color filters; and a microlens on the color filter array layer, wherein the pixel division structure includes a core; and a lateral pattern structure on a sidewall of the core, and wherein the core includes a first filling pattern including a conductive material; and a second filling pattern in a space formed by the first filling pattern, a sidewall of the second filling pattern being covered by the first filling pattern, and wherein a thickness of a portion of the first filling pattern contacting the second filling pattern gradually decreases in the vertical direction from a top of the first filling pattern toward a bottom of the first filling pattern.

In accordance with an aspect of the disclosure, an image sensor includes a pixel division structure extending through a substrate in a vertical direction, the vertical direction being substantially perpendicular to an upper surface of the substrate, the pixel division structure defining unit pixel regions in which unit pixels are respectively formed; a light sensing element in each of the unit pixel regions; a color filter array layer on the substrate, the color filter array layer comprising color filters; and a microlens on the color filter array layer, wherein the pixel division structure includes a core; and a lateral pattern structure on a sidewall of the core, wherein the core includes a first portion and a second portion, wherein the first portion of the core includes only a first filling pattern comprising a conductive material, and wherein the second portion of the core includes the first filling pattern and a second filling pattern, a sidewall of the second filling pattern being covered by the first filling pattern.

In accordance with an aspect of the disclosure, an image sensor includes a first substrate defining a first region, a second region, a third region, and a fourth region at an inside of the first substrate and a space under and over the first substrate, the second region surrounding the first region, the third region surrounding the second region, and the fourth region surrounding the third region; a first insulating interlayer on the first substrate, the first insulating interlayer containing first wirings in the third region; a second insulating interlayer on the first insulating interlayer, the second insulating interlayer containing second wirings in the third region; a second substrate on the second insulating interlayer; a pixel division structure in the second substrate positioned in the first region and the second region, the pixel division structure defining unit pixel regions in which unit pixels are respectively formed; a light sensing element in each of the unit pixel regions of the second substrate; a transfer gate (TG) extending through a lower portion of the second substrate, the TG contacting the light sensing element; a floating diffusion (FD) region at a lower portion of the second substrate adjacent to the TG; a lower planarization layer on the second substrate; a color filter array layer on the lower planarization layer, the color filter array layer including color filters; an interference blocking structure between adjacent ones of the color filters; a microlens on the color filter array layer; a light blocking metal pattern on the lower planarization layer in the second region; a through via structure extending through the lower planarization layer, the second substrate, the second insulating interlayer, and an upper portion of the first insulating interlayer in the third region, the through via structure commonly contacting the first wirings and the second wirings; a light blocking color filter layer on the light blocking metal pattern and the through via structure in the second region and the third region; and a pad extending through the lower planarization layer and an upper portion of the second substrate in the fourth region.

In accordance with an aspect of the disclosure, a camera module includes a prism configured to change a path of a light incident from an outside by reflecting the incident light; an optical path folding element (OPFE) configured to change an optical zoom ratio of light reflected from the prism; an image sensing device configured to sense an image of an object using light incident from the OPFE; and a storage device configured to store image data generated from the image sensing device, wherein the image sensing device includes a substrate including a first region in which active pixels are formed and a second region in which optical black (OB) pixels are formed, the second region surrounding the first region; a pixel division structure extending through the substrate in a vertical direction, the vertical direction being substantially perpendicular to an upper surface of the substrate, the pixel division structure defining unit pixel regions in which unit pixels are respectively formed; a light sensing element in each of the unit pixel regions; a color filter array layer on the substrate, the color filter array layer including color filters; and a microlens on the color filter array layer, wherein the pixel division structure includes a core; and a lateral pattern structure on a sidewall of the core, and wherein the core includes a first filling pattern including polysilicon doped with p-type impurities or n-type impurities at a first impurity concentration; and a second filling pattern in a space formed by the first filling pattern, a sidewall of the second filling pattern being covered by the first filling pattern, and the second filling pattern including polysilicon doped with p-type impurities or n-type impurities at a second impurity concentration different from the first impurity concentration.

In accordance with an aspect of the disclosure, an electronic device includes a camera module configured to sense an object to generate image data; an application processor (AP) configured to receive and process the image data generated from the camera module; a power management integrated circuit (PMIC) configured to provide a power supply voltage to the camera module; and an external memory configured to store the image data processed by the AP, wherein the camera module includes an image sensing device configured to sense an image of the object using light reflected from the object, wherein the image sensing device includes a substrate including a first region in which active pixels are formed and a second region in which optical black (OB) pixels are formed, the second region surrounding the first region; a pixel division structure extending through the substrate in a vertical direction, the vertical direction being substantially perpendicular to an upper surface of the substrate, the pixel division structure defining unit pixel regions in which unit pixels are respectively formed; a light sensing element in each of the unit pixel regions; a color filter array layer on the substrate, the color filter array layer comprising color filters; and a microlens on the color filter array layer, wherein the pixel division structure includes a core; and a lateral pattern structure on a sidewall of the core, and wherein the core includes a first filling pattern including polysilicon doped with p-type impurities or n-type impurities at a first impurity concentration; and a second filling pattern in a space formed by the first filling pattern, a sidewall of the second filling pattern being covered by the first filling pattern, and the second filling pattern comprising polysilicon doped with p-type impurities or n-type impurities at a second impurity concentration different from the first impurity concentration.

In accordance with an aspect of the disclosure, a method of manufacturing an image sensor includes forming a pixel division structure in a substrate, the pixel division structure defining unit pixel regions in which unit pixels are respectively formed; forming a light sensing element in each of the unit pixel regions; forming a color filter array layer on the substrate, the color filter array layer comprising color filters; and forming a microlens on the color filter array layer, wherein the forming of the pixel division structure includes forming a first trench partially extending through the substrate, the first trench including a first region having a first width and a second region having a second width greater than the first width; forming a lateral layer structure on a sidewall of the first trench; forming a first filling layer to fill the first region of the first trench and partially fill the second region of the first trench, the first filling layer including polysilicon doped with p-type impurities or n-type impurities; partially etching the first filling layer to form a first filling pattern in the first trench, the first filling pattern filling a lower portion of the first region of the first trench, and the first filling pattern being on a bottom of a lower portion of the second region of the first trench and a sidewall of the lower portion of the second region of the first trench; and forming a second filling pattern to fill a remaining portion of the lower portion of the second region of the first trench, the second filling pattern including undoped polysilicon.

In accordance with an aspect of the disclosure, a method of manufacturing an image sensor includes forming a pixel division structure in a substrate, the pixel division structure defining unit pixel regions in which unit pixels are respectively formed; forming a light sensing element in each of the unit pixel regions; forming a color filter array layer on the substrate, the color filter array layer including color filters; and forming a microlens on the color filter array layer, wherein forming the pixel division structure includes forming a first trench partially extending through the substrate, the first trench including a first region having a first width and a second region having a second width greater than the first width; forming a lateral layer structure on a sidewall of the first trench; forming a first filling layer to fill the first region of the first trench and partially fill the second region of the first trench, the first filling layer including undoped polysilicon; partially etching the first filling layer to form a first filling pattern in the first trench, the first filling pattern filling a lower portion of the first region of the first trench, and the first filling pattern being on a bottom of a lower portion of the second region of the first trench and a sidewall of the lower portion of the second region of the first trench; and forming a second filling pattern to fill a remaining portion of the lower portion of the second region of the first trench, the second filling pattern including polysilicon doped with p-type impurities or n-type impurities.

In accordance with an aspect of the disclosure, a method of manufacturing an image sensor includes forming a pixel division structure in a substrate, the pixel division structure defining unit pixel regions in which unit pixels are respectively formed; forming a light sensing element in each of the unit pixel regions; forming a color filter array layer on the substrate, the color filter array layer including color filters; and forming a microlens on the color filter array layer, wherein forming the pixel division structure includes forming a first trench partially extending through the substrate, the first trench including a first region having a first width and a second region having a second width greater than the first width; forming a lateral layer structure on a sidewall of the first trench; forming a first filling layer to fill the first region of the first trench and partially fill the second region of the first trench; partially etching the first filling layer to form a first filling pattern in the first trench, the first filling pattern filling a lower portion of the first region of the first trench, and the first filling pattern being on a bottom of a lower portion of the second region of the first trench and a sidewall of the lower portion of the second region of the first trench; and forming a second filling pattern to fill a remaining portion of the lower portion of the second region of the first trench.

The pixel division structure of the image sensor in accordance with example embodiments may include a core including p-type or n-type impurities. During the formation of the core, a seam or void may not be generated, and the size of any seam or void that is generated may not be enlarged during subsequent thermal treatment. Thus, dark current may be effectively reduced by applying negative bias to the core. Additionally, the core may include the conductive material, and thus the RC-delay may be reduced.

### BRIEF DESCRIPTION OF DRAWINGS

FIGS. 1 and 2 are horizontal cross-sectional views illustrating a pixel division structure included in an image sensor in accordance with example embodiments, and FIGS. 3 and 4 are vertical cross-sectional views illustrating the pixel division structure.

FIGS. 5 to 20 are plan views and cross-sectional views illustrating a method of forming a pixel division structure in accordance with example embodiments.

FIGS. 21 and 22 are cross-sectional views illustrating a pixel division structure in accordance with example embodiments.

FIGS. 23 and 24 are cross-sectional views illustrating a pixel division structure in accordance with example embodiments.

FIGS. 25 and 26 are cross-sectional views illustrating a pixel division structure in accordance with example embodiments.

FIG. 27 is a plan view illustrating an image sensor in accordance with example embodiments, and FIG. 28 is a cross-sectional view taken along line C-C′ of FIG. 27 illustrating a method of manufacturing the image sensor.

FIGS. 29 to 36 are cross-sectional views illustrating a method of manufacturing an image sensor in accordance with example embodiments.

FIG. 37 is a block diagram illustrating an electronic device including an image sensor in accordance with example embodiments, and FIG. 38 is a block diagram illustrating a camera module included in the electronic device of FIG. 37.

### DESCRIPTION OF EMBODIMENTS

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Image sensors, camera modules including the image sensors, electronic devices including the camera modules, and methods of manufacturing the image sensors in accordance with example embodiments will be more clearly understood from the following detailed description taken in conjunction with the accompanying drawings.

It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second or third element, component, region, layer or section without departing from the teachings of inventive concepts.

First to fourth regions I, II, III and IV may refer to only an inside of a reference substrate, a first substrate and/or a second substrate. Alternatively, the first to fourth regions I, II, III and IV may also refer to spaces over and under the reference substrate, the first substrate and/or the second substrate.

A direction substantially parallel to the reference substrate or the first substrate and/or the second substrate may be referred to as a horizontal direction, and a direction substantially perpendicular to the surface of the reference substrate or the first substrate and/or the second substrate may be referred to as a vertical direction. In the specification, up vs. down, on and over vs. beneath and under, upper surface vs. lower surface, and upper portion vs. lower portion are relative conceptions so as to describe opposite sides in the vertical direction, and each wording may have opposite meanings according to the specific parts to be explained in the specifications.

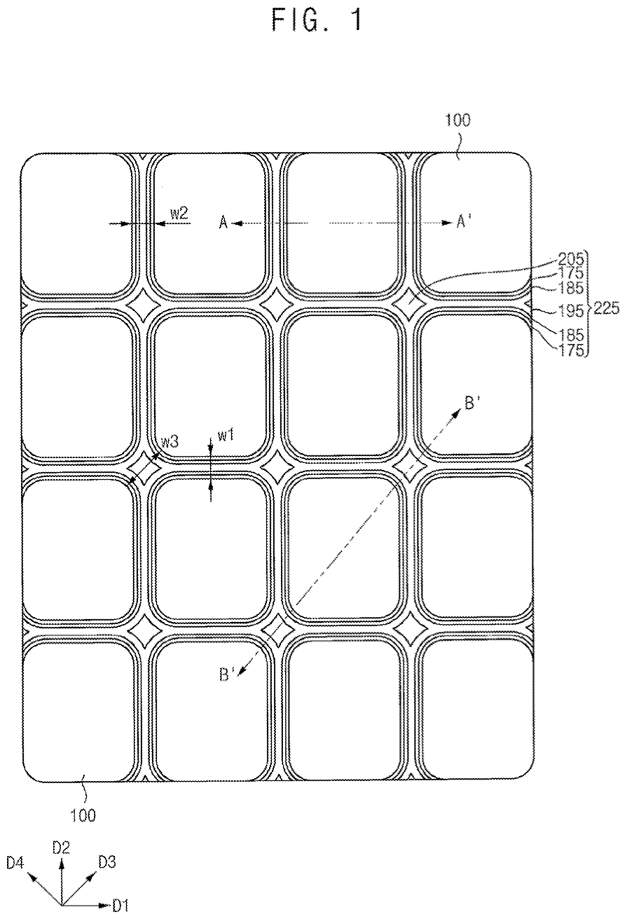

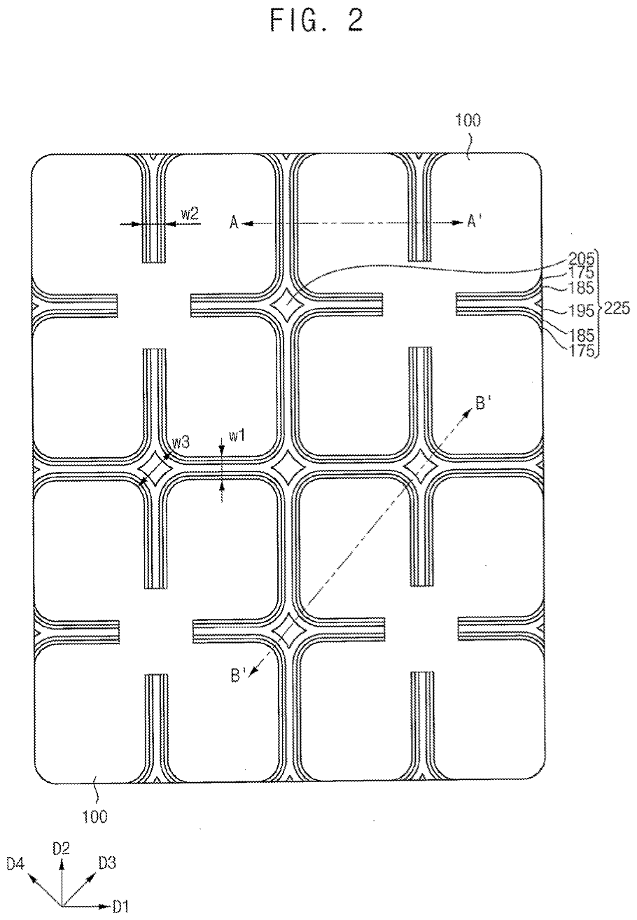

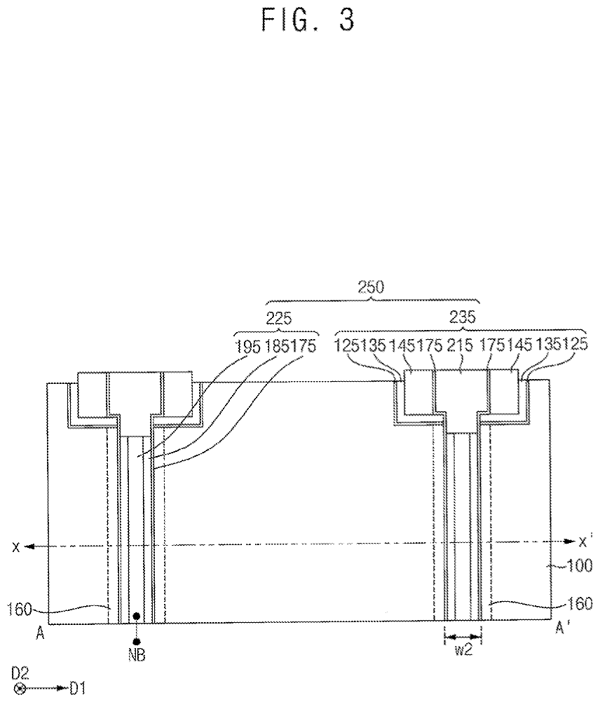

FIGS. 1 and 2 are horizontal cross-sectional views illustrating a pixel division structure included in an image sensor in accordance with example embodiments, and FIGS. 3 and 4 are vertical cross-sectional views illustrating the pixel division structure. Particularly, FIGS. 1 and 2 are horizontal cross-sectional views taken along lines X-X′ of FIGS. 3 and 4, and FIGS. 3 and 4 are vertical cross-sectional views taken along lines A-A′ and B-B′ of FIGS. 1 and 2, respectively.

Hereinafter, two directions substantially perpendicular to each other among the horizontal directions may be defined as first and second directions D1 and D2, respectively, and two directions substantially perpendicular to each other and having acute angles with respect to the first and second directions D1 and D2 may be defined as third and fourth directions D3 and D4, respectively.

Referring to FIGS. 1 to 4, a pixel division structure 250 may extend through a substrate 100 in the vertical direction, and may have a lattice shape in a plan view.

In example embodiments, the substrate 100 may include silicon, germanium, silicon-germanium, or a III-V group compound semiconductor, such as GaP, GaAs, or GaSb. In example embodiments, a p-type well doped with p-type impurities may be formed partially or entirely in the substrate 100.

Unit pixel regions in which unit pixels are formed, respectively, may be defined by the pixel division structure 250 in the substrate 100. In example embodiments, the unit pixels may be arranged in the horizontal direction to form a pixel array.

FIG. 1 shows a plurality of unit pixels are spaced apart from each other by the pixel division structure 250 in the first and second directions D1 and D2, and FIG. 2 shows that four neighboring unit pixels are connected with each other.

The unit pixels may be spaced apart from each other in the first direction D1 by a second width W2, and may be spaced apart from each other in the second direction D2 by a first width W1. Additionally, opposite corners in the third direction D3 or fourth direction D4 of the unit pixels may be spaced apart from each other by a third width W3.

In example embodiments, the first and second widths W1 and W2 may be the same as or different from each other, and may be less than the third width W3.

In example embodiments, the pixel division structure 250 may include a second filling pattern structure 225 and a first filling pattern structure 235 stacked in the vertical direction. The first filling pattern structure 235 may be stacked on the second filling pattern structure 225. The second filling pattern structure 225 may include a core extending in the vertical direction and a lateral pattern structure covering a sidewall of the core.

In example embodiments, the core may include second and third filling patterns 195 and 205, and the lateral pattern structure may include a lower portion of the first lateral pattern 175 and a second lateral pattern 185.

In example embodiments, the second filling pattern structure 225 may have the first width W1 or the second width W2 between neighboring unit pixels in the first direction D1 or the second direction D2, while the second filling pattern structure 225 may have the third width W3 greater than the first and second widths W1 and W2 between neighboring unit pixels in the third direction D3 or the fourth direction D4.

In example embodiments, the core may include only the second filling pattern 195 at a first portion of the second filling pattern structure 225 having the first and second widths W1 and W2, while the core may include both of the second and third filling patterns 195 and 205 at a second portion of the second filling pattern structure 225 having the third width W3.

In example embodiments, the second filling pattern 195 may include polysilicon doped with p-type impurities, e.g., boron or doped with n-type impurities, e.g., phosphorus with a first impurity concentration. The third filling pattern 205 may include polysilicon doped with p-type impurities, e.g., boron or doped with n-type impurities, e.g., phosphorus with a second impurity concentration.

In an example embodiment, the second and third filling patterns 195 and 205 may be doped with the same impurities, and the first impurity concentration of the second filling pattern 195 may be greater than the second impurity concentration of the third filling pattern 205. Additionally, the impurities may be uniformly doped in the second filling pattern 195, while an impurity concentration of a portion of the third filling pattern 205 adjacent to the second filling pattern 195 may be greater than an impurity concentration of a portion of the third filling pattern 205 distal to the second filling pattern 195. In an example embodiment, the impurity concentration in the third filling pattern 205 may gradually decrease as a distance from the second filling pattern 195 increases, and a portion of the third filling pattern 205 farthest from the second filling pattern 195 may not include impurities.

In example embodiments, the third filling pattern 205 may have a width gradually decreasing from a top toward a bottom thereof. In example embodiments, a portion of the second filling pattern 195 adjacent to the third filling pattern 205 may have a width gradually increasing from a top toward a bottom thereof.

In example embodiments, an upper surface of a portion of the core including the second and third filling patterns 195 and 205 may have a concave shape. For example, a center portion of the upper surface of the core including the second and third filling patterns 195 and 205 may protrude in a downward direction.

The second lateral pattern 185 may cover a sidewall of the core, and the lower portion of the first lateral pattern 175 may cover a sidewall of the second lateral pattern 185. The first lateral pattern 175 may include an oxide, e.g., silicon oxide, and the second lateral pattern 185 may include a nitride, e.g., silicon nitride.

The first filling pattern structure 235 may include a fourth filling pattern 215 on the core and the second lateral pattern 185, an upper portion of the first lateral pattern 175 on a sidewall of the fourth filling pattern 215, a first filling pattern 145 covering an outer sidewall of the upper portion of the first lateral pattern 175, and first and second pads 125 and 135 covering an outer sidewall and a lower surface of the first filling pattern 145.

In example embodiments, the fourth filling pattern 215 may have a lower portion having a relatively small width and an upper portion having a relatively large width. The fourth filling pattern 215 may include an oxide, e.g., silicon oxide.

The lower portion of the first lateral pattern 175 may be included in the second filling pattern structure 225, and the upper portion of the first lateral pattern 175 may be included in the first filling pattern structure 235. The lower and upper portions of the first lateral pattern 175 may be connected to each other and integrally formed. The upper portion of the first lateral pattern 175 may cover a sidewall of the lower portion of the fourth filling pattern 215 and a lower surface and a sidewall of the upper portion of the fourth filling pattern 215.

The first filling pattern 145 may cover an outer sidewall of a portion of the first lateral pattern 175 on the sidewall of the upper portion of the fourth filling pattern 215. The first filling pattern 145 may include an oxide, e.g., silicon oxide.

The second pad 135 may cover the sidewall and the lower surface of the first filling pattern 145, while may not cover a sidewall of the upper portion of the first filling pattern 145. The first pad 125 may cover an outer sidewall and a lower surface of the second pad 135. The first pad 125 may include an oxide, e.g., silicon oxide, and the second pad 135 may include a nitride, e.g., silicon nitride.

In example embodiments, a width of the first filling pattern structure 235 may be greater than a width of the second filling pattern structure 225.

An impurity region 160 may be formed at a portion of the substrate 100 adjacent to the pixel division structure 250, and may include p-type impurities, e.g., boron.

In the image sensor including the pixel division structure 250, electrons may flow at a boundary between the pixel division structure 250 and a light sensing element to generate dark current, and a negative bias may be applied to the core included in the pixel division structure 250 so that the flow of electrons may be captured by the impurity region 160 to decrease the dark current. However, if the core of the pixel division structure 250 includes undoped polysilicon, a seam or void may be generated during the formation of the core, and the seam or void may be enlarged during a subsequent thermal treatment. Thus, even though a negative bias is applied to the core, the flow of electrons may not be captured by the impurity region 160, so that the dark current may not decrease.

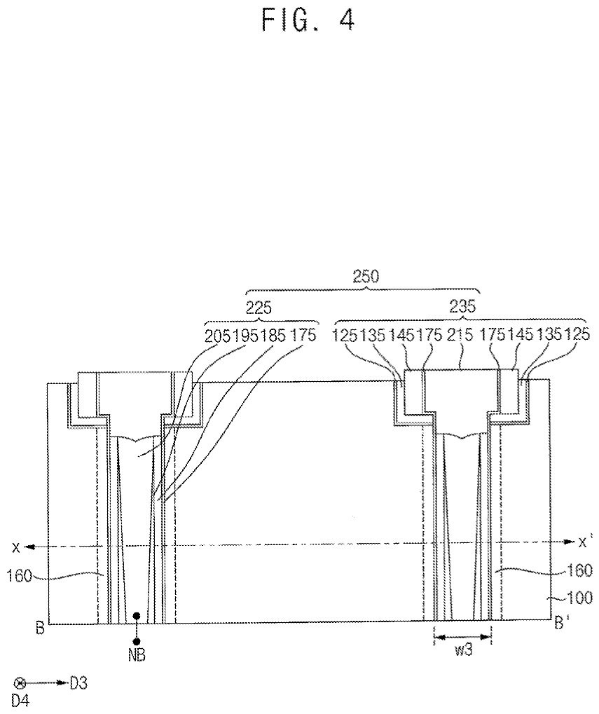

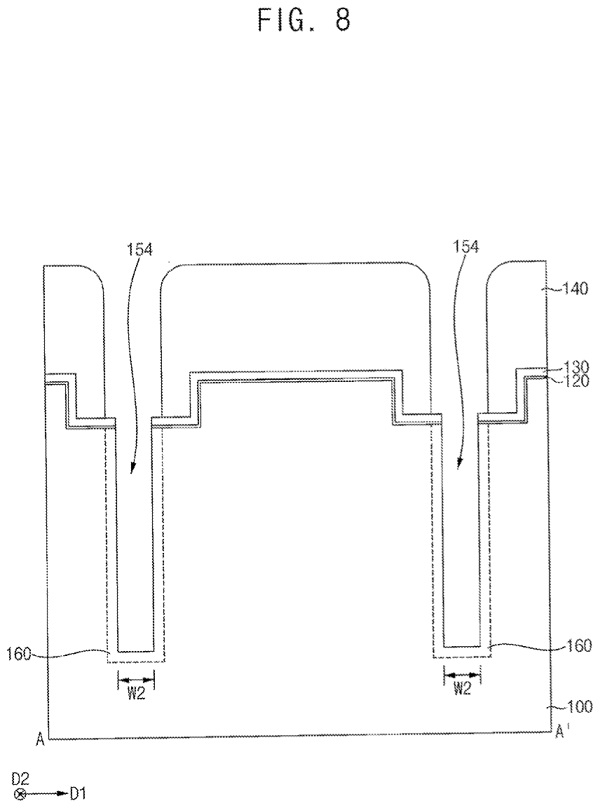

However, in example embodiments, the core may include the second filling pattern 195 doped with p-type or n-type impurities and/or the third filling pattern 205. Thus, a seam or void may not be formed during the formation of the second and third filling patterns 195 and 205, and even if the seam or void is generated, the seam or void may not be enlarged, as illustrated below with reference to FIGS. 5 to 20. Thus, a negative bias (NB) may be applied to the core so that the flow of electrons may be captured by the impurity region 160 to decrease the dark current. Additionally, the core may include a conductive material, so as to decrease RC-delay.

FIGS. 5 to 20 are plan views and cross-sectional views illustrating a method of forming a pixel division structure in accordance with example embodiments.

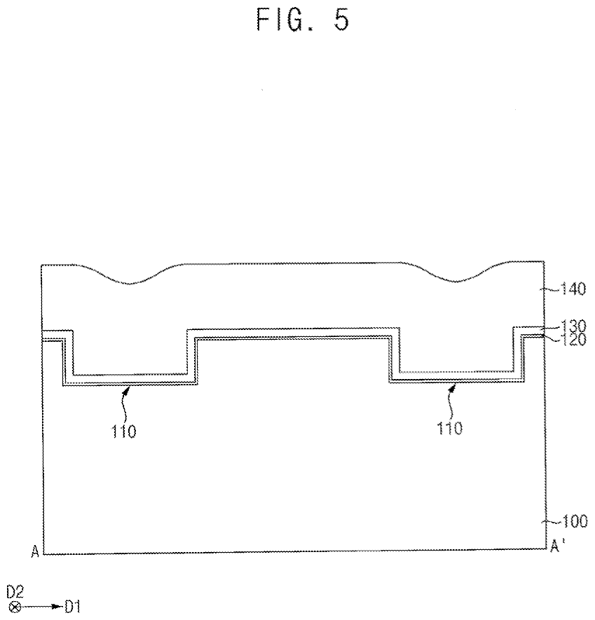

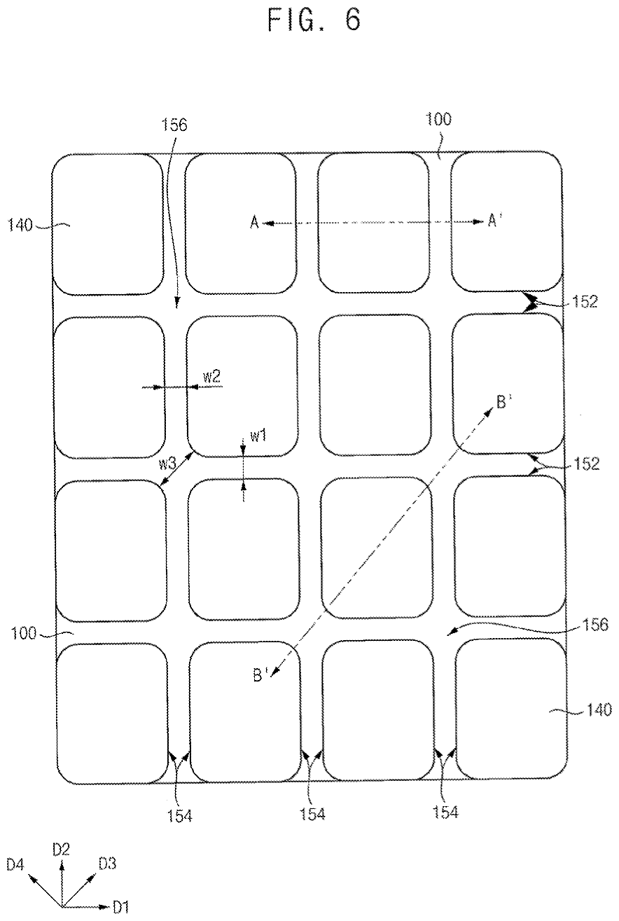

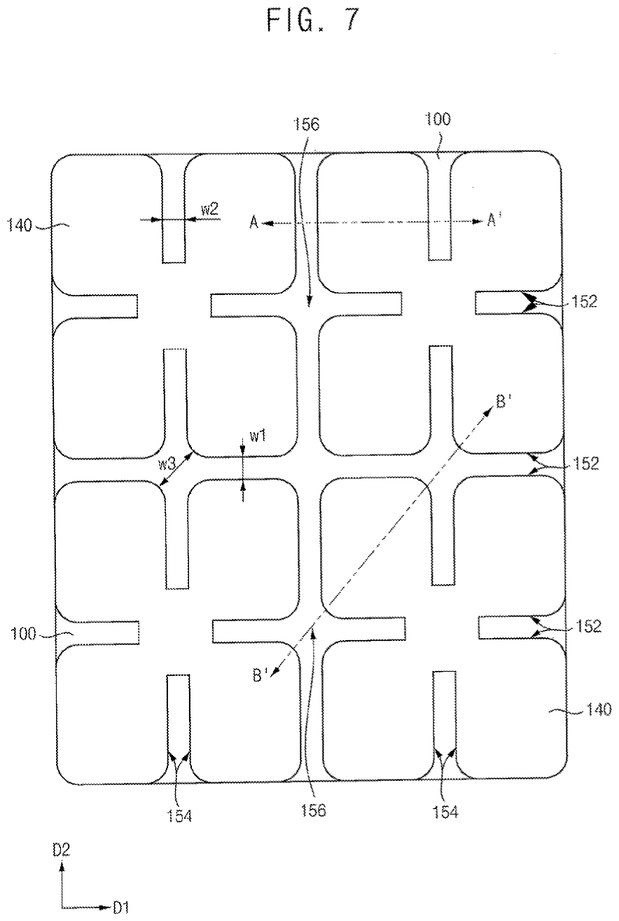

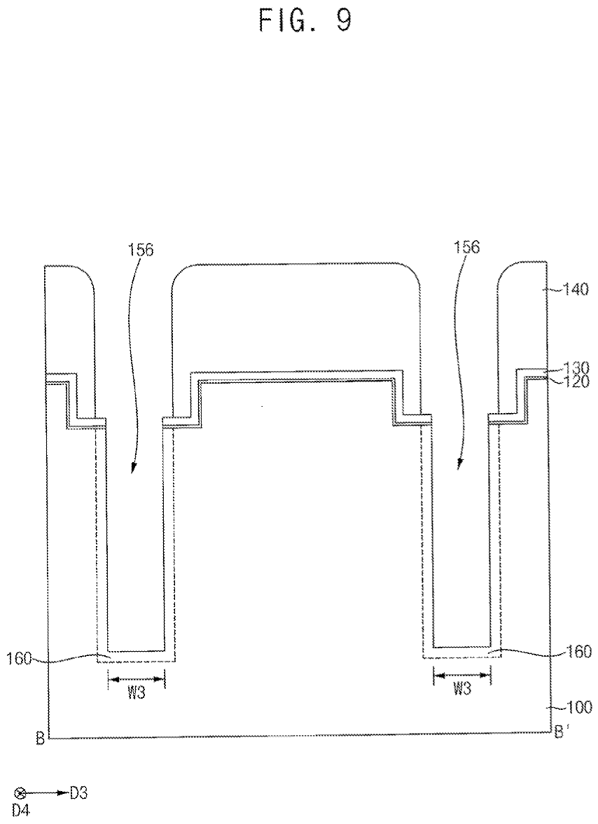

Particularly, FIGS. 6 and 7 are the plan views, FIGS. 5, 8, 10, 12, 14 and 19 are cross-sectional views taken along lines A-A′ of corresponding plan views, respectively, and FIGS. 9, 11, 13, 15-18 and 20 are cross-sectional views taken along lines B-B′ of corresponding plan views, respectively. FIGS. 6 and 7 are plan views of pixels arranged in different patterns from each other.

Referring to FIG. 5, an upper portion of a substrate 100 may be removed to form a first trench 110, and a first pad layer 120, a second pad layer 130 and a first filling layer 140 may be sequentially stacked on the substrate 100 having the first trench 110 thereon.

In example embodiments, the first trench 110 may extend in the first direction D1, and a plurality of first trenches 110 may be spaced apart from each other in the second direction D2. Additionally, the first trench 110 may extend in the second direction D2, and a plurality of first trenches 110 may be spaced apart from each other in the first direction D1. Thus, the first trench 110 may have a lattice pattern in a plan view.

Referring to FIGS. 6 to 9, the first filling layer 140, the second pad layer 130, the first pad layer 120 and the substrate 100 may be sequentially removed by an etching process to form second and third trenches 152 and 154.

The etching process may be, e.g., a dry etching process, and thus may be performed with an etching mask on the first filling layer 140. Due to the difference between etching rates of the first filling layer 140 and the second pad layer 130, each of the second and third trenches 152 and 154 may be formed to have a width in the first and second pad layers 120 and 130 less than a width in the first filling layer 140.

Hereinafter, in each of the second and third trenches 152 and 154, a portion extending through all of a portion of the substrate 100 and the first and second pad layers 120 and 130 may be referred to as a lower portion, and a portion extending through the first filling layer 140 may be referred to as an upper portion. Additionally, a width of each of the second and third trenches 152 and 154 may refer to a width of the lower portion thereof, unless there are other descriptions about the width of the second and third trenches 152 and 154.

In example embodiments, the second trench 152 may extend in the first direction D1, and may have a first width W1 in the second direction D2. Additionally, the third trench 154 may extend in the second direction D2, and may have a second width W2 in the first direction D1. Thus, the second and third trenches 152 and 154 may cross each other, and portions of the second and third trenches 152 and 154 meeting each other may be referred to as a fourth trench 156. The fourth trench 156 may include lower and upper portions as the second and third trenches 152 and 154, and a width of the fourth trench 156 may refer to a width of the lower portion thereof.

In example embodiments, a third width W3 of the fourth trench 156 in the third direction D3 may be greater than the first and second widths W1 and W2 of the second and third trenches 152 and 154. The first and second widths W1 and W2 may be substantially the same as or different from each other.

In example embodiments, the second trench 152 may overlap a portion of the first trench 110 extending in the first direction D1 in the vertical direction, and the third trench 154 may overlap a portion of the first trench 110 extending in the second direction D2 in the vertical direction. The first and second widths W1 and W2 of the second and third trenches 152 and 154, respectively, may be less than widths of the first trench 110 in the second and first directions D2 and D1, respectively, and depths of the second and third trenches 152 and 154 may be greater than a depth of the first trench 110.

P-type impurities, e.g., boron may be doped into portions of the substrate 100 adjacent to the second and fourth trenches 152, 154 and 156 by an ion implantation process to form an impurity region 160.

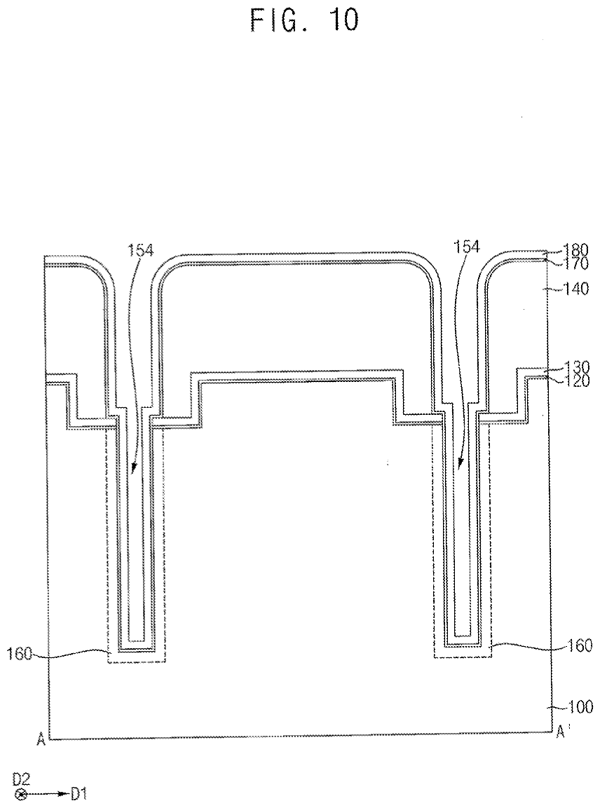

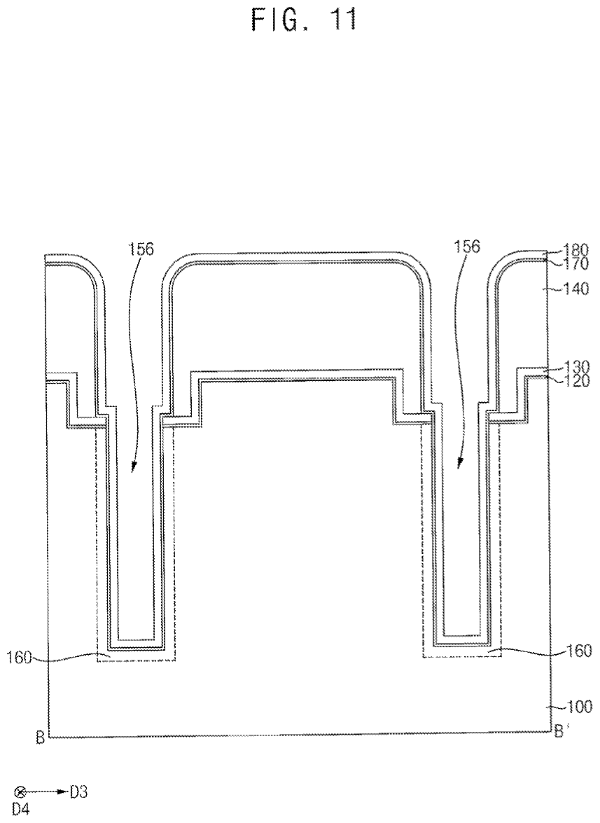

Referring to FIGS. 10 and 11, a lateral layer structure may be formed on inner walls of the second to fourth trenches 152, 154 and 156 and an upper surface of the first filling layer 140.

In example embodiments, the lateral layer structure may include first and second lateral layers 170 and 180 sequentially stacked and including different materials. The first lateral layer 170 may include an oxide, e.g., silicon oxide, and the second lateral layer 180 may include a nitride, e.g., silicon nitride, silicon carbonitride, silicon oxycarbonitride, etc. FIGS. 10 and 11 show that the second lateral layer 180 is a single layer, however, the disclosure may not be limited thereto, and the second lateral layer 180 may have a multi-layered structure including a plurality of layers sequentially stacked and including some of the above materials.

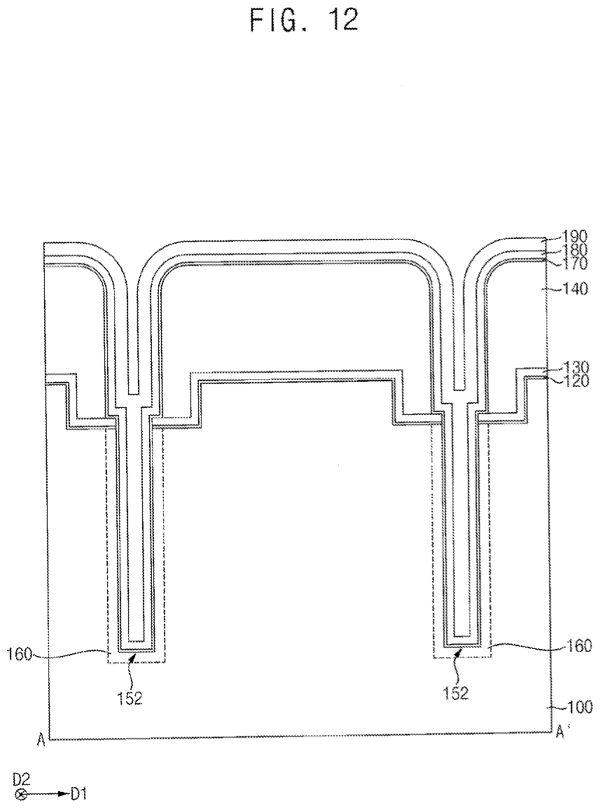

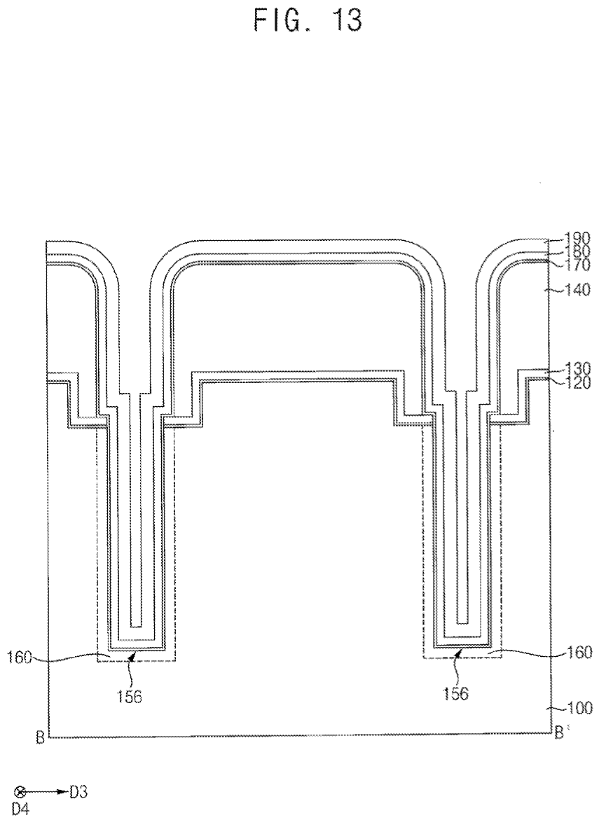

Referring to FIGS. 12 and 13, a second filling layer 190 may be formed on the lateral layer structure.

In example embodiments, the second filling layer 190 may entirely fill a lower portion of each of the second and third trenches 152 and 154 having a relatively small width, however, the second filling layer 190 may not entirely fill a lower portion of the fourth trench 156 having a relatively large width, and may be formed on a sidewall and a lower surface of the fourth trench 156. The second filling layer 190 may not entirely fill an upper portion of each of the second to fourth trenches 152, 154 and 156, but may be formed on a sidewall thereof.

In example embodiments, the second filling layer 190 may include polysilicon doped with p-type impurities, e.g., boron or n-type impurities, e.g., phosphorus, and thus may include a conductive material.

In an example embodiment the second filling layer 190 may be formed by a low pressure chemical vapor deposition (LPCVD) process or a plasma enhanced chemical vapor deposition (PECVD) process using a silicon source gas, e.g., silane (SiH₄) gas and a boron source gas, e.g., diborane (B₂H₆) gas or a phosphorus source gas, e.g., phosphine (PH₃) gas.

As the second filling layer 190 includes polysilicon doped with p-type impurities or n-type impurities, the second filling layer 190 may be deposited at a relatively low temperature and a relatively low rate when compared to a layer including undoped polysilicon. Thus, the second filling layer 190 may have a relatively high step coverage when compared to the layer including undoped polysilicon.

Alternatively, the second filling layer 190 may be formed to include undoped polysilicon, and boron or phosphorus may be doped into the second filling layer 190 by, e.g., an ion implantation process, a plasma doping process, a gas phase doping process, etc., so that the second filling layer 190 may include polysilicon doped with boron or phosphorus.

In example embodiments, the second filling layer 190 may include polysilicon doped with, e.g., carbon or oxygen in addition to p-type impurities or n-type impurities. In this case, CH₃ gas or CH₂ gas may be additionally used or N₂O gas or NO gas may be additionally used during the LPCVD process or the PECVD process.

When the second filling layer 190 includes polysilicon doped with carbon or oxygen, silicon atoms in the second filling layer 190 may not diffuse or migrate when a subsequent thermal treatment is performed. Thus, even if a seam or void is generated in the second filling layer 190, it may not be enlarged.

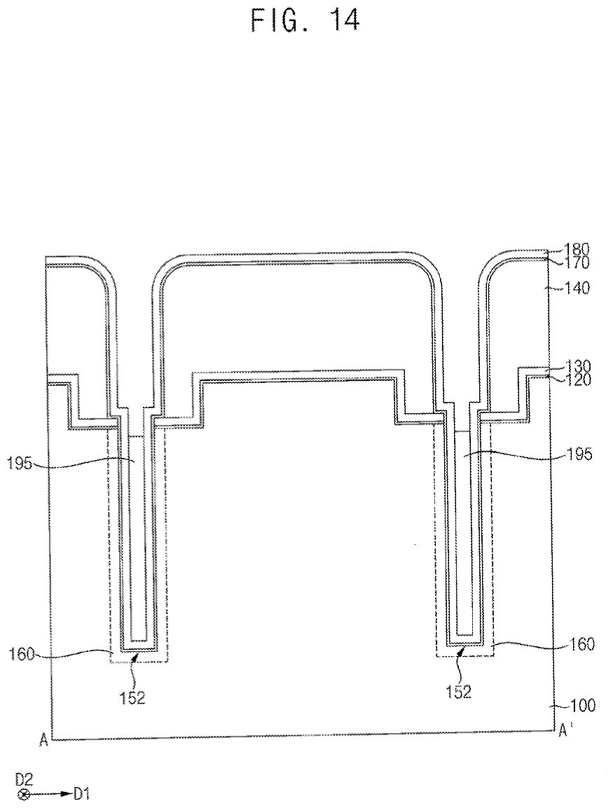

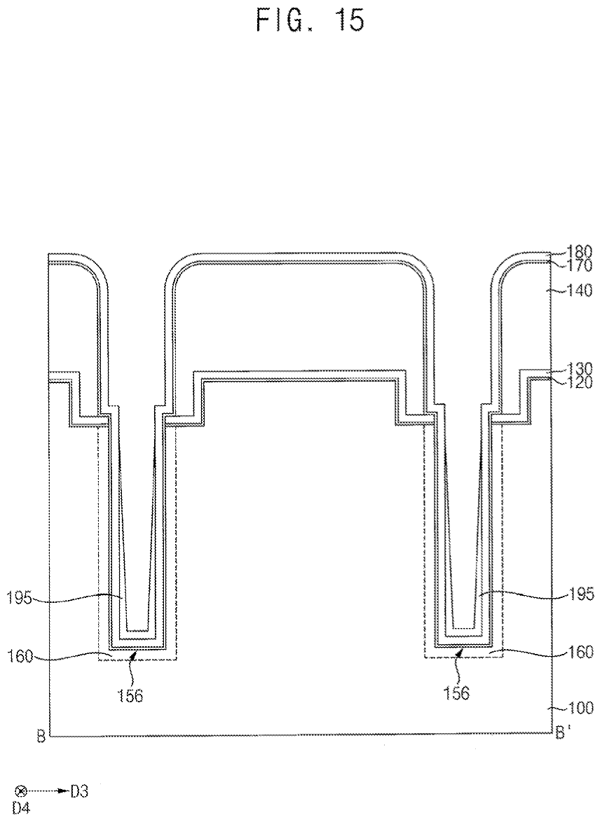

Referring to FIGS. 14 and 15, an etching process may be performed on the second filling layer 190 so that portions of the second filling layer 190 at the upper portions of the second to fourth trenches 152, 154 and 156 may be removed to form a second filling pattern 195.

In example embodiments, the etching process may be performed using an etching gas including chlorine (Cl₂) gas, and may be an anisotropic etching process. Thus, the portions of the second filling layer 190 at the upper portions of the second and third trenches 152 and 154 may be entirely removed, and the portion of the second filling layer 190 at the lower portion of each of the second and third trenches 152 and 154 may remain as a second filling pattern 195.

Additionally, the portion of the second filling layer 190 at the upper portion of the fourth trench 156 may be entirely removed, and the portion of the second filling layer 190 at the lower portion of the fourth trench 156 may be partially removed so that the second filling pattern 195 having a tapered shape in which a width gradually increases from a top toward a bottom thereof may remain. Thus, a remaining portion of the lower portion of the fourth trench 156 that is partially filled with the second filling pattern 195 may have a width gradually decreasing from a top toward a bottom thereof.

In example embodiments, the deposition process for forming the second filling layer 190 and the etching process of the second filling layer 190 may be performed in-situ in the same chamber, or ex-situ in different chambers.

In an example embodiment, an uppermost surface of the second filling pattern 195 remaining in each of the second to fourth trenches 152, 154 and 156 may be lower than a lower surface of the first pad layer 120, however, the disclosure may not be limited thereto. That is, the uppermost surface of the second filling pattern 195 in each of the second to fourth trenches 152, 154 and 156 may be lower than or substantially coplanar with a bottom of the upper portion of each of the second to fourth trenches 152, 154 and 156, that is, an upper surface of the second pad layer 130 in the first trench 110.

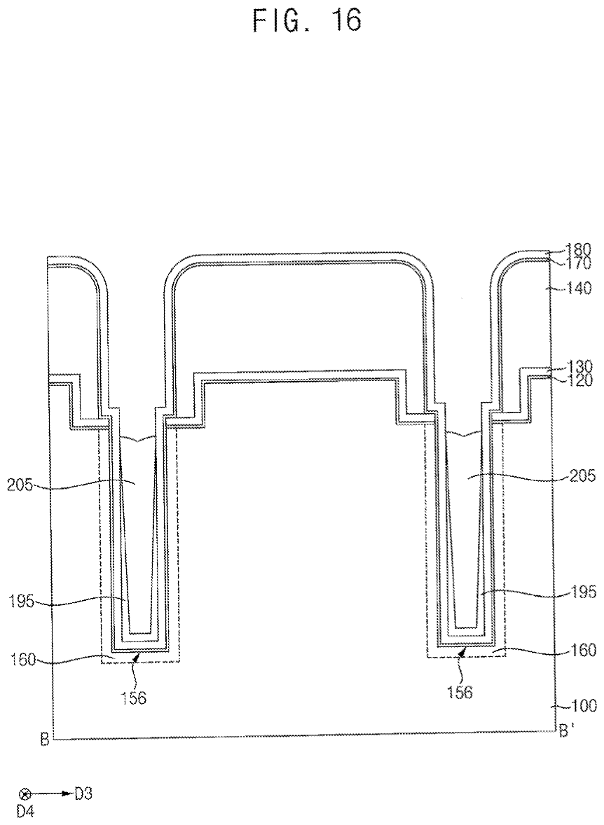

Referring to FIG. 16, a third filling layer may be formed on the second filling pattern 195 to fill the second to fourth trenches 152, 154 and 156, and may be etched until an upper surface of the portion of the second filling pattern 195 in each of the second and third trenches 152 and 154 is exposed.

Thus, the portions of the third filling layer in the second and third trenches 152 and 154 may be entirely removed, and a third filling pattern 205 may be formed on the second filling pattern 195 at a lower portion of the fourth trench 156. The third filling pattern 205 may have a concave upper surface. In an example embodiment, a cross-section of the third filling pattern 205 in the vertical direction may have a V-shape.

The third filling layer may be formed by a deposition process, e.g., an LPCVD process, a PECVD process, etc. As illustrated above, the remaining portion of the lower portion of the fourth trench 156 may have the width gradually decreasing from a top toward a bottom thereof, and thus no void or seam may be formed when the third filling layer is deposited at the lower portion of the fourth trench 156.

In example embodiments, the third filling pattern 205 may include undoped polysilicon. In other example embodiments, the third filling pattern 205 may include polysilicon doped with carbon or oxygen.

Alternatively, the third filling pattern 205 may include polysilicon doped with n-type or p-type impurities, like the second filling pattern 195.

The second and third filling patterns 195 and 205 at the lower portion of each of the second to fourth trenches 152, 154 and 156 may form a core.

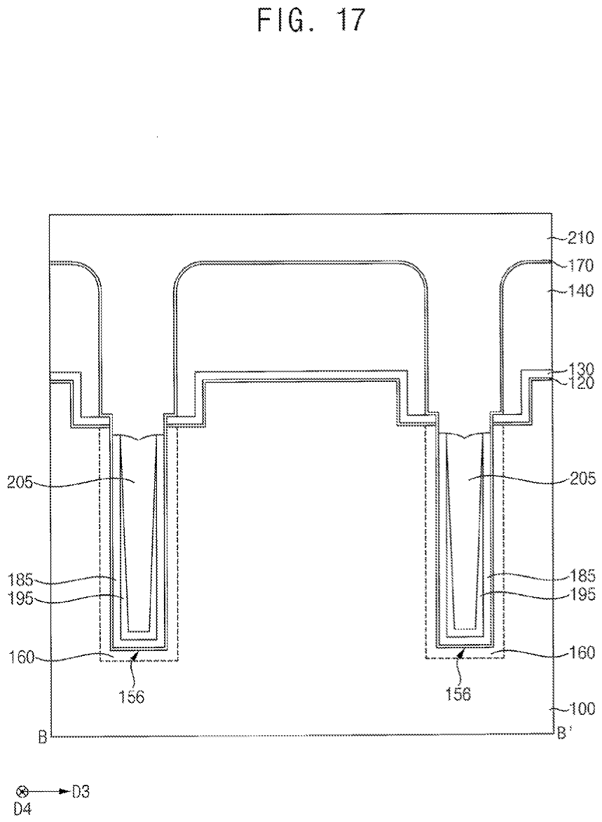

Referring to FIG. 17, a portion of the second lateral layer 180 at a height higher than an upper surface of the core, that is, an upper portion of the second lateral layer 180 may be removed so that a second lateral pattern 185 may remain at a lower portion of each of the second to fourth trenches 152, 154 and 156.

In example embodiments, the upper portion of the second lateral layer 180 may be removed by a wet etching process. As the upper portion of the second lateral layer 180 is removed, a surface of an upper portion of the first lateral layer 170 may be exposed.

A fourth filling layer 210 may be formed on surfaces of the core, the second lateral pattern 185 and the upper portion of the first lateral layer 170 to fill the second to fourth trenches 152, 154 and 156.

The fourth filling layer 210 may include an oxide, e.g., silicon oxide.

A thermal treatment process may be performed on the substrate 100 having the above structures thereon. Thus, even if the third filling pattern 205 includes undoped polysilicon, p-type or n-type impurities doped in the second filling pattern 195 adjacent to the third filling pattern 205 may partially diffuse to the third filling pattern 205 so that a portion or an entire portion of the third filling pattern 205 may include the p-type or n-type impurities. However, an impurity concentration of the p-type or n-type impurities in the third filling pattern 205 may be lower than an impurity concentration of the p-type or n-type impurities in the second filling pattern 195, and the impurity concentration of the third filling pattern 205 may decrease as a distance from the second filling pattern 195 increases. Thus, in some embodiments, a portion of the third filling pattern 205 distal from the second filling pattern 195 may include no impurities.

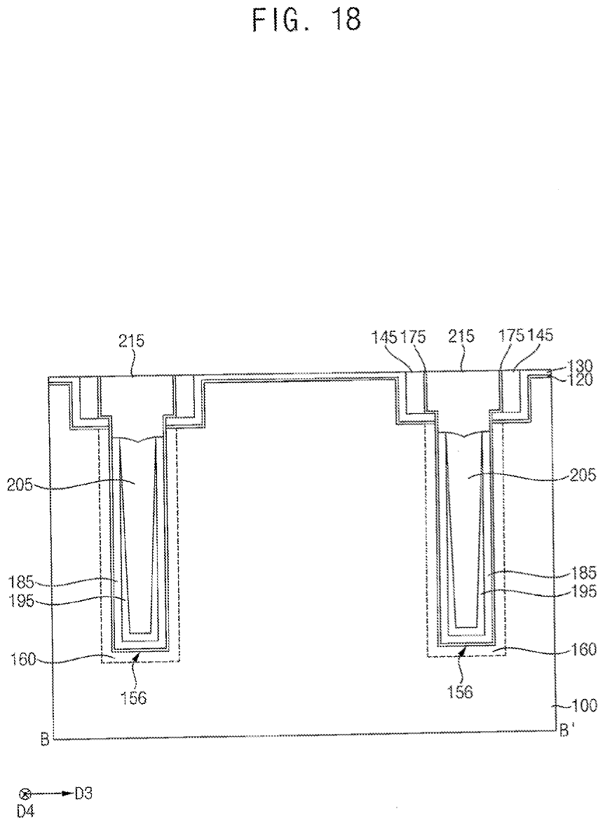

Referring to FIG. 18, the fourth filling layer 210, the first lateral layer 170 and the first filling layer 140 may be planarized until an upper surface of the second pad layer 130 is exposed.

In example embodiments, the planarization process may include a chemical mechanical polishing (CMP) process and/or an etch back process.

By the planarization process, the fourth filling layer 210 may be transformed into a fourth filling pattern 215, the first lateral layer 170 may be transformed into a first lateral pattern 175, and the first filling layer 140 may be transformed into a first filling pattern 145. The first and second lateral patterns 175 and 185 may form a lateral pattern structure.

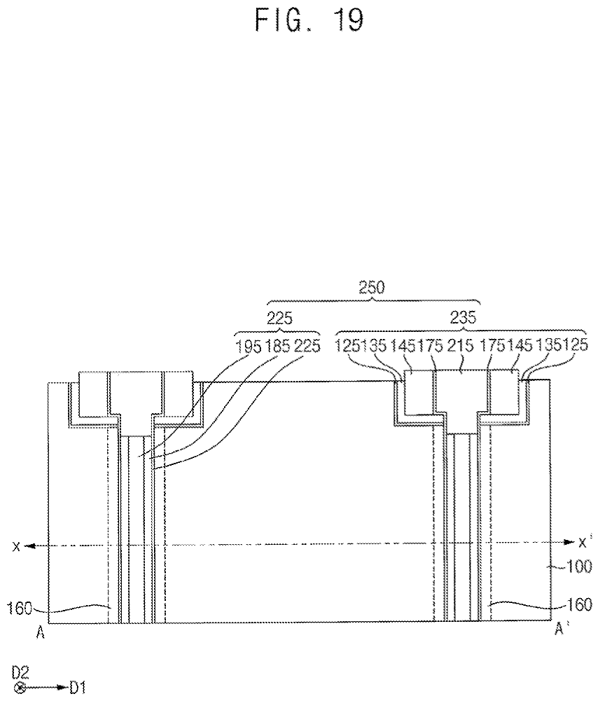

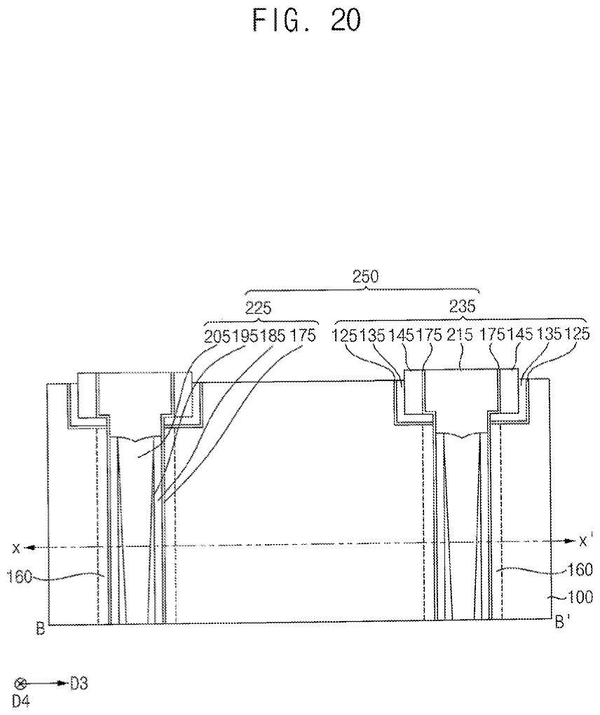

Referring to FIGS. 19 and 20, the second pad layer 130 may be partially removed to form a second pad 135, and thus an upper surface of the first pad layer 120 may be partially exposed.

The second pad layer 130 may be removed by, e.g., a wet etching process.

An ion implantation process may be performed to form a light sensing element in the substrate 100, and the exposed portion of the first pad layer 120 may be removed. Thus, a portion of the first pad layer 120 may remain as a first pad 125, and an upper surface of the substrate 100 may be exposed.

Hereinafter, the fourth filling pattern 215, and an upper portion of the first lateral pattern 175 on a sidewall of the fourth filling pattern 215, the first filling pattern 145 and the first and second pads 125 and 135 may be referred to as a first filling pattern structure 235. Additionally, the core including the second and third filling patterns 195 and 205 and the lateral pattern structure including a lower portion of the first lateral pattern 175 and the second lateral pattern 185 may be referred to as a second filling pattern structure. The core may include only the second filling pattern 195 in the lower portion of each of the second and third trenches 152 and 154.

The second filling pattern structure 225 and the first filling pattern structure 235 stacked in the vertical direction may be referred to as a pixel division structure 250.

Referring to FIGS. 1 and 4, a lower portion of the substrate 100 may be removed.

In example embodiments, the lower portion of the substrate 100 may be removed by, e.g., a grinding process and/or a planarization process such as a CMP process. Thus, a lower portion of the second filling pattern structure included in the pixel division structure 250 may be removed.

That is, lower portions of the core and the lateral pattern structure included in the second filling pattern structure 225 may be removed, and the pixel division structure 250 may extend through the entire substrate 100.

The pixel division structure 250 may be formed by the above processes.

As illustrated above, the second filling pattern 195 in each of the second to fourth trenches 152, 154 and 156 may include polysilicon doped with p-type or n-type impurities, and thus may be deposited at a relatively low temperature and at a low rate. Accordingly, the second filling pattern 195 that may be formed by a deposition process may not have a void or seam therein.

Additionally, the second filling pattern 195 may further include impurities, e.g., carbon or oxygen, and silicon included in the second filling pattern 195 may not diffuse or migrate into neighboring structures by a subsequent thermal treatment. Accordingly, even if a void or seam is formed in the second filling pattern 195, the void or seam may not be enlarged by the thermal treatment.

The third filling pattern 205 may be further formed in addition to the second filling pattern 195 in the fourth trench 156 having a relatively large width. The second filling pattern 195 may have a tapered shape, and thus the lower portion of the fourth trench 156 may have a width gradually decreasing from a top toward a bottom thereof. Accordingly, when the third filling pattern 205 is formed, a void or seam may not be formed in the third filling pattern 205.

In some embodiments, the second filling layer 190 includes polysilicon doped with p-type or n-type impurities, and the third filling layer includes undoped polysilicon, however, the disclosure may not be limited thereto.

For example, the second filling layer 190 may include undoped polysilicon, and the third filling layer may include polysilicon doped with p-type or n-type impurities. However, even though the second filling layer 190 included undoped polysilicon, p-type or n-type impurities doped in the third filling layer may diffuse into the second filling layer 190 by a subsequent thermal treatment so that the second filling layer 190 may include the p-type or n-type impurities. The impurity concentration of the second filling layer 190 may be less than that of the third filling layer.

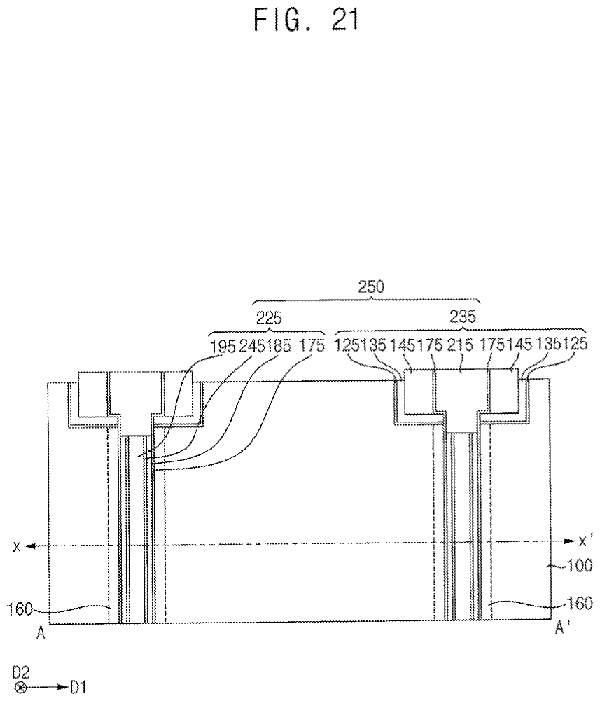

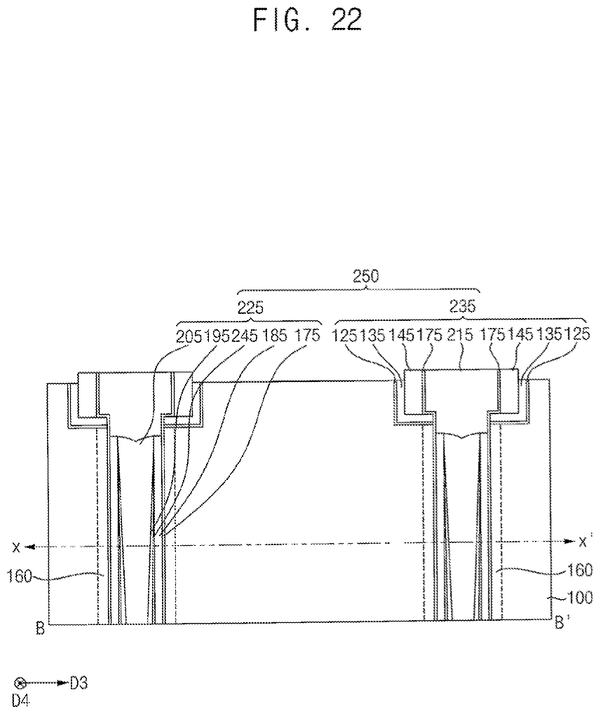

FIGS. 21 and 22 are cross-sectional views illustrating a pixel division structure in accordance with example embodiments. This pixel division structure may be substantially the same as or similar to that of FIGS. 1 to 4, except for further including a seed pattern, and thus repeated explanations thereof are omitted herein.

Referring to FIGS. 21 and 22, the pixel division structure 250 may include the second and first filling pattern structures 225 and 235, and the second filling pattern structure 225 may include a core and a lateral pattern structure.

In example embodiments, the lateral pattern structure may include a seed pattern 245 in addition to the lower portion of the first lateral pattern 175 and the second lateral pattern 185.

The seed pattern 245 may be formed by following processes.

Before forming the second filling layer 190 illustrated with reference to FIGS. 12 and 13, a seed layer may be formed on the lateral layer structure. In example embodiments, the seed layer may be formed by a deposition process using a source gas including diisopropylamino silane (DIPAS), hexachlorodisilane (HCDS), etc., and thus may include, e.g., silicon carbonitride.

As the seed layer is formed, the second filling layer 190 may be easily formed on the lateral layer structure.

When the upper portion of the second lateral layer 180 is removed by the process illustrated with reference to FIG. 17, an upper portion of the seed layer may also be removed so that the seed pattern 245 may remain at a lower portion of each of the second to fourth trenches 152, 154 and 156.

In an example embodiment, the seed layer may be formed on the second filling pattern 195 and the lateral layer structure before forming the third filling layer, and in this case, the seed pattern 245 may be formed between the second filling pattern 195 and the third filling pattern 205.

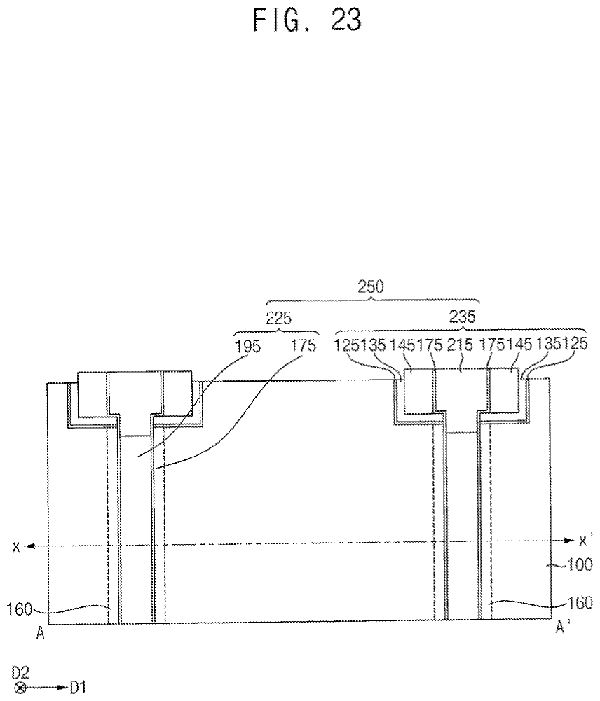

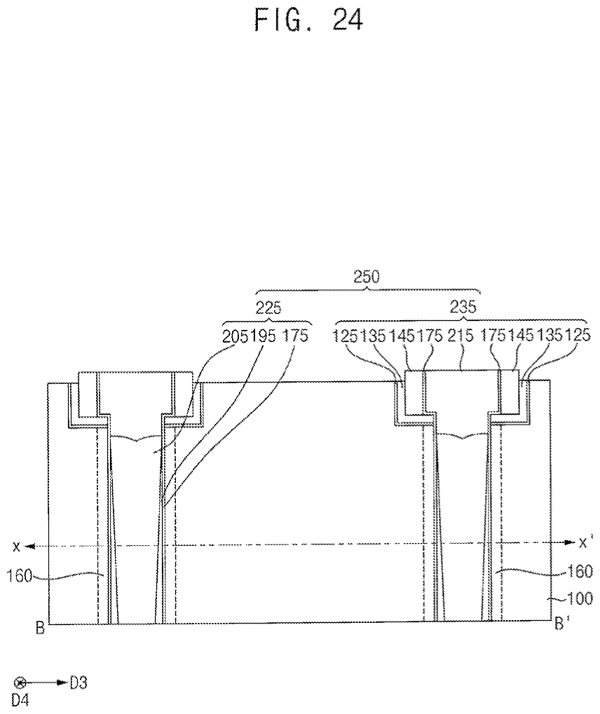

FIGS. 23 and 24 are cross-sectional views illustrating a pixel division structure in accordance with example embodiments. This pixel division structure may be substantially the same as or similar to that of FIGS. 1 to 4, except for not including the second lateral pattern, and thus repeated explanations thereof are omitted herein.

Referring to FIGS. 23 and 24, the pixel division structure 250 may include the second and first filling pattern structures 225 and 235, and the second filling pattern structure 225 may include a core and a lateral pattern structure.

In example embodiments, the lateral pattern structure may not include the second lateral pattern, but may include only the lower portion of the first lateral pattern 175.

In some embodiments, when the lateral layer structure is formed by the process illustrated with reference to FIGS. 10 and 11, the lateral layer structure may include only the first lateral layer 170 including an oxide, e.g., silicon oxide.

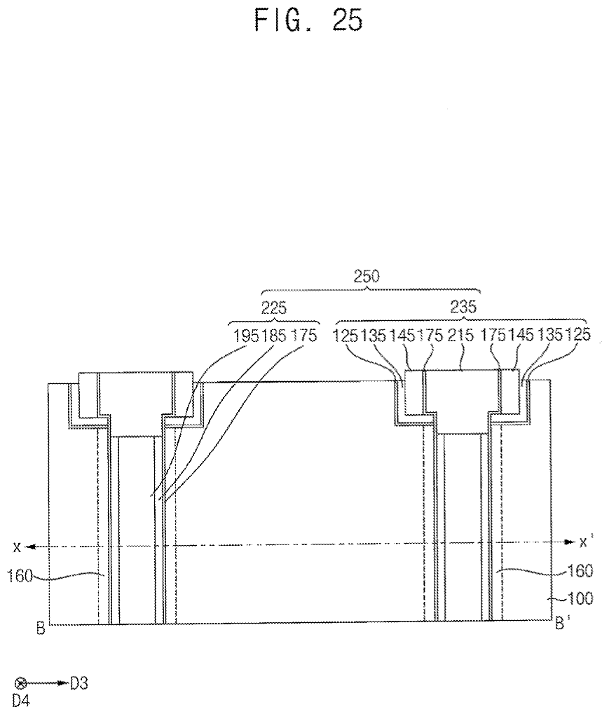

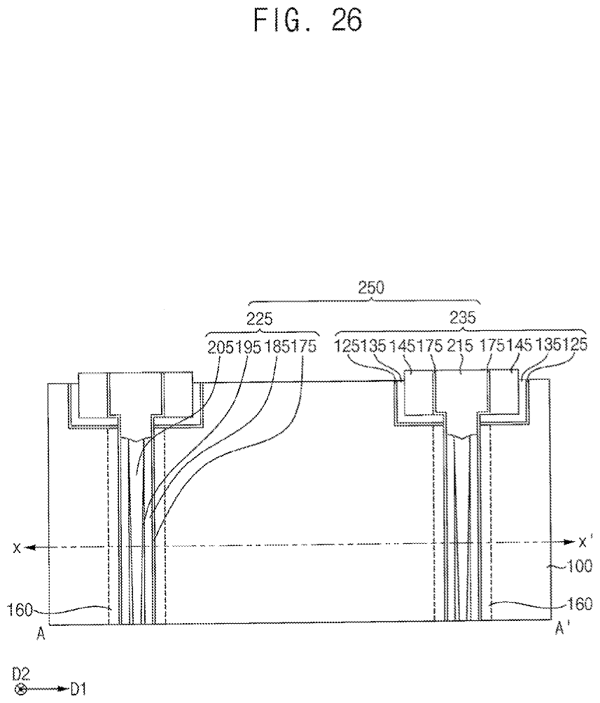

FIGS. 25 and 26 are cross-sectional views illustrating a pixel division structure in accordance with example embodiments. This pixel division structure may be substantially the same as or similar to that of FIGS. 1 to 4, except for the shape and material of the core, and thus repeated explanations thereof are omitted herein.

Referring to FIG. 25, the pixel division structure 250 may include the second and first filling pattern structures 225 and 235, and the second filling pattern structure 225 may include a core and a lateral pattern structure.

In example embodiments, not only the core in each of the second and third trenches 152 and 154 but also the core in the fourth trench 156 may not include the third filling pattern, but may include only the second filling pattern 195.

In some embodiments, during the formation of the second filling layer 190 illustrated with reference to FIGS. 12 and 13, the second filling layer 190 may be formed to fill not only the second and third trenches 152 and 154 but also the fourth trench 156, and the etching process of the second filling layer 190 illustrated with reference to FIGS. 14 and 15 may be performed, so that the second filling pattern 195 fills the lower portion of each of the second to fourth trenches 152, 154 and 156 and including p-type or n-type impurities.

Referring to FIG. 26, the pixel division structure 250 may include the second and first filling pattern structures 225 and 235, and the second filling pattern structure 225 may include a core and a lateral pattern structure.

In example embodiments, not only the core in each of the second and third trenches 152 and 154 but also the core in the fourth trench 156 may include the third filling pattern 205 in addition to the second filling pattern 195.

In some embodiments, during the formation of the second filling layer 190 illustrated with reference to FIGS. 12 and 13, the second filling layer 190 may be formed to partially fill each of the second to fourth trenches 152, 154 and 156, and the etching process of the second filling layer 190 illustrated with reference to FIGS. 14 and 15 may be performed to form the second filling pattern 195 having a tapered shape. The processes illustrated with reference to FIG. 16 may be performed to form the third filling pattern 205 in each of the second to fourth trenches 152, 154 and 156.

However, the second filling layer 190 may include undoped polysilicon, and the third filling layer may include polysilicon doped with p-type or n-type impurities. However, as described above, the p-type or n-type impurities doped in the third filling pattern 205 may diffuse into the second filling pattern 195 by a subsequent thermal treatment, so that the second filling pattern 195 may also include the p-type or n-type impurities.

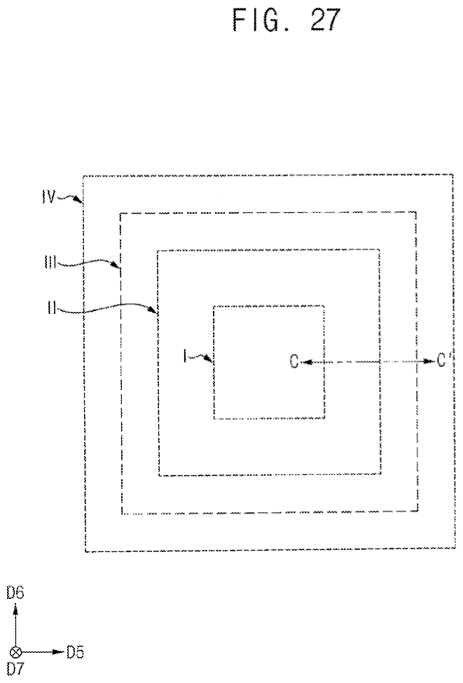

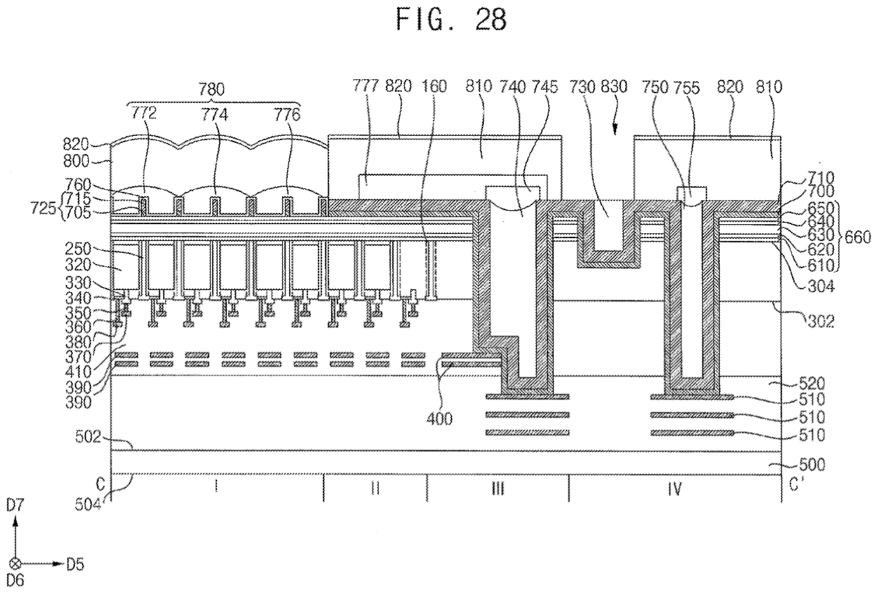

FIG. 27 is a plan view illustrating an image sensor in accordance with example embodiments, and FIG. 28 is a cross-sectional view taken along line C-C′ of FIG. 27 illustrating an image sensor.

This image sensor may include a pixel division structure substantially the same as or similar to the pixel division structure illustrated with reference to FIGS. 1 to 4, and thus repeated explanations thereof are omitted herein. However, the pixel division structure of FIGS. 27 and 28 is overturned from the pixel division structure of FIGS. 1 to 4, and thus an upside and a downside of the pixel division structures of FIGS. 1 to 4 and those of FIGS. 27 and 28 are opposite to each other.

This image sensor may also include pixel division structures substantially the same as or similar to the pixel division structures illustrated with reference to FIGS. 23 to 26.

Hereinafter, two directions substantially parallel to a first surface 302 of a first substrate 300 may be defined as fifth and sixth directions D5 and D6, respectively, and a direction substantially perpendicular to the first surface 302 of the first substrate 300 may be defined as a seventh direction D7. In example embodiments, the fifth and sixth directions D5 and D6 may be substantially perpendicular to each other.

Referring to FIGS. 27 and 28, the image sensor may include a second substrate 500, a second insulating interlayer 520, a first insulating interlayer 410, the first substrate 300 and a lower planarization layer 660 sequentially stacked in the seventh direction D7 in first to fourth regions I, II, III and IV. A color filter array layer 780, a microlens 800 and a transparent protection layer 820 may be sequentially stacked on the lower planarization layer 660 in the first region I, and a barrier pattern 700 and a conductive pattern 710 may be sequentially stacked on the lower planarization layer 660 in the second and third regions II and III. A light blocking color filter layer 777 may be formed on the conductive pattern 710, an upper planarization layer 810 may be formed on the conductive pattern 710 to cover the light blocking color filter layer 777, and the transparent protection layer 820 may be formed on the upper planarization layer 810. The upper planarization layer 810 and the transparent protection layer 820 may be sequentially stacked on the lower planarization layer 660 in the fourth region IV.

The image sensor may further include first to third wirings 370, 380 and 390 and first and second vias 350 and 360 contained in the first insulating interlayer 410, the pixel division structure 250 extending through the first substrate 300 in the seventh direction D7, a light sensing element 320 in each unit pixel region defined by the pixel division structure 250, a transfer gate (TG) 330 extending through a lower portion of the first substrate 300 and having a lower portion protruding from the first surface 302 of the first substrate 300 and covered by the first insulating interlayer 410, and a floating diffusion (FD) region 340 at a lower portion of the first substrate 300 adjacent to the TG 330 in the first and second regions I and II.

The image sensor may further include an interference blocking structure 725 between color filters 772 and 774 included in the color filter array layer 780 and a protection layer 760 covering a surface of the interference blocking structure 725 on the lower planarization layer 660 in the first region I.

The image sensor may further include a fourth wiring 400 contained in the first insulating interlayer 410, a fifth wiring 510 contained in the second insulating interlayer 520, and a first through via structure extending through the lower planarization layer 660, the first substrate 300, the first insulating interlayer 410 and an upper portion of the second insulating interlayer 520 to commonly contact the fourth and fifth wirings 400 and 510 in the third region III.

The image sensor may further include the fifth wiring 510 contained in the second insulating interlayer 520, a conductive pad 730 extending through the lower planarization layer 660 and an upper portion of the first substrate 300, and a second through via structure extending through the lower planarization layer 660, the first substrate 300, the first insulating interlayer 410 and an upper portion of the second insulating interlayer 520 to contact the fifth wiring 510 in the fourth region IV.

The image sensor may further include various transistors at lower portions of the first substrate 300 adjacent to the first surface 302 of the first substrate 300. The transistors may include, e.g., source follower transistors, reset transistors and select transistors. The TG 330 and the FD region 340 may form a transfer transistor. That is, the light sensing element 320 may serve as a source region of the transfer transistor, and the FD region 340 may serve as a drain region of the transfer transistor.

In example embodiments, in a plan view, the first region I may have a shape of a square or rectangle, the second region II may surround the first region I, the third region III may surround the second region II, and the fourth region IV may surround the third region III, however, the disclosure may not be limited thereto.

In example embodiments, the first region I may be an active pixel region in which active pixels are formed, the second region II may be an OB pixel region in which OB pixels are formed, the third region III may be a stack region in which the first through via structure is formed, and the fourth region IV may be a pad region in which the conductive pads 730 are formed.

The first substrate 300 may include the first surface 302 and a second surface 304 opposite to the first surface 302, and the second substrate 500 may include a third surface 502 and a fourth surface 504 opposite to the third surface 502. FIG. 28 shows that the first surface 302 is disposed under the second surface 304, and the third surface 502 is disposed over the fourth surface 504.

In example embodiments, p-type impurities may be doped into a portion or an entire portion of the first substrate 300 to form a p-type well.

The pixel division structure 250 may extend in the seventh direction D7 in the first and second regions I and II, and may have a lattice pattern arranged in the fifth and sixth directions D5 and D6 in a plan view. A plurality of unit pixel regions defined by the pixel division structure 250 may be arranged in the fifth and sixth directions D5 and D6.

In example embodiments, the light sensing element 320 may be a portion of a photodiode (PD). The light sensing element 320 may be an impurity region doped with n-type impurities in the p-well in the first and second regions I and II of the first substrate 300, and thus the light sensing element 320 and the p-well may form a PN junction diode.

The light sensing element 320 may be formed in each of the unit pixel regions defined by the pixel division structure 250 in the first and second regions I and II. However, the light sensing element 320 may not be formed in some of the unit pixel regions in the second region II.

The TG 330 may include a buried portion extending from the first surface 302 of the first substrate 300 in the seventh direction D7 upwardly and a protrusion portion under the buried portion and having a bottom surface lower than the first surface 302 of the first substrate 300.

The FD region 340 may be formed at a portion of the first substrate 300 adjacent to the first surface 302 and the TG 330, and may be doped with n-type impurities.

The first via 350 may contact the TG 330, and may be connected to the first wiring 370. The second via 360 may contact the FD region 340, and may be connected to the second wiring 380.

Vias and wirings that may be connected to the various transistors, that is, the source follower transistors, the reset transistor and the select transistors may be further formed in the first insulating interlayer 410 in the first and second regions I and II. FIG. 28 shows that the third and fourth wirings 390 and 400 are formed at two levels in the seventh direction D7, however, the disclosure may not be limited thereto.

Each of the first and second insulating interlayers 410 and 520 may include an oxide, e.g., silicon oxide or a low-k dielectric material.

In an example embodiments, the lower planarization layer 660 may include first, second, third, fourth and fifth layers 610, 620, 630, 640 and 650 sequentially stacked in the seventh direction D7. For example, the first to fifth layers 610, 620, 630, 640 and 650 may include aluminum oxide, hafnium oxide, silicon oxide, silicon nitride and hafnium oxide, respectively.

The interference blocking structure 725 may be formed on the lower planarization layer 660 to overlap the pixel division structure 250 in the seventh direction D7, and may have a lattice pattern in a plan view. In example embodiments, the interference blocking structure 725 may include first and second interference blocking patterns 705 and 715 stacked in the seventh direction D7. The first interference blocking pattern 705 may include a metal nitride, and the second interference blocking pattern 715 may include a metal. Alternatively, the second interference blocking pattern 715 may include a low refractive index material (LRIM).

The protection layer 760 may include a metal oxide, e.g., aluminum oxide.

The color filter array layer 780 may be formed on the protection layer 760, and sidewalls and bottom surfaces of the first color filter 772, the second color filter 774 and the third color filter 776 included in the color filter array layer 780 may be covered by the protection layer 760. The first color filter 772, the second color filter 774 and the third color filter 776 may be a green color filter G, a blue color filter B and a red color filter R, respectively.

In example embodiments, the light blocking color filter layer 777 may include the same composition as a second color filter 774, which may absorb a light having a relatively large wavelength among the first color filter 772, the second color filter 774 and the third color filter 776 included in the color filter array layer 780.

The light blocking color filter layer 777 may be formed on the lower planarization layer 660 and the first through via structure in the second and third regions II and III, and may be spaced apart by a given distance in the horizontal direction from the first region I.

The first through via structure may include a fifth filling pattern 740 extending in the seventh direction D7 through the lower planarization layer 660, the first substrate 300, the first insulating interlayer 410 and an upper portion of the second insulating interlayer 520, a conductive pattern 710 covering a lower surface and a sidewall of the fifth filling pattern 740, a barrier pattern 700 covering a lower surface and a sidewall of the conductive pattern 710, and a first capping pattern 745 on an upper surface of the fifth filling pattern 740.

The second through via structure may include a sixth filling pattern 750 extending in the seventh direction D7 through the lower planarization layer 660, the first substrate 300, the first insulating interlayer 410 and an upper portion of the second insulating interlayer 520, the conductive pattern 710 covering a lower surface and a sidewall of the sixth filling pattern 750, the barrier pattern 700 covering the lower surface and the sidewall of the conductive pattern 710, and a second capping pattern 755 on an upper surface of the sixth filling pattern 750.

Each of the fifth and sixth filling patterns 740 and 750 may include, e.g., a LRIM, and each of the first and second capping patterns 745 and 755 may include, e.g., a photoresist material.

A portion of the conductive pattern 710 included in the first through via structure may commonly contact the fourth and fifth wirings 400 and 510 so that the fourth and fifth wirings 400 and 510 may be electrically connected with each other, and a portion of the conductive pattern 710 included in the second through via structure may contact the fifth wiring 510 so as to be electrically connected thereto.

The conductive pattern 710 may be included in the first and second through via structures, and may also be formed on the lower planarization layer 660 in the second to fourth regions II, III and IV. A portion of the conductive pattern 710 in the second and third regions II and III may be referred to as a light blocking metal pattern.

The conductive pattern 710 may include a metal, e.g., tungsten, and the barrier pattern 700 may include a metal nitride, e.g., titanium nitride.

The conductive pad 730 may be electrically connected with an outer wiring, and may be a path through which electrical signals may be input into the active pixels and/or the OB pixels, or electrical signals may be output from the active pixels and/or the OB pixels. The conductive pad 730 may include a metal, e.g., aluminum. A lower surface and a sidewall of the conductive pad 730 may be covered by the conductive pattern 710.

The microlens 800 may be formed on the color filter array layer 780 and the protection layer 760 in the first region I, and the upper planarization layer 810 may be formed on the light blocking color filter layer 777 and the second through via structure in the second to fourth regions II, III and IV, however, the upper planarization layer 810 may include a third opening 830 exposing an upper surface of the conductive pad 730 in the fourth region IV. In example embodiments, the microlens 800 and the upper planarization layer 810 may include substantially the same material, e.g., a photoresist material having a high transmittance.

The transparent protection layer 820 may be formed on the microlens 800 and the upper planarization layer 810. The transparent protection layer 820 may include, e.g., SiO, SiOC, SiC, SiCN, etc.

The image sensor may include the pixel division structure 250 illustrated with reference to FIGS. 1 to 4, which may include the core including the conductive material, and thus the dark current and the RC-delay may decrease.

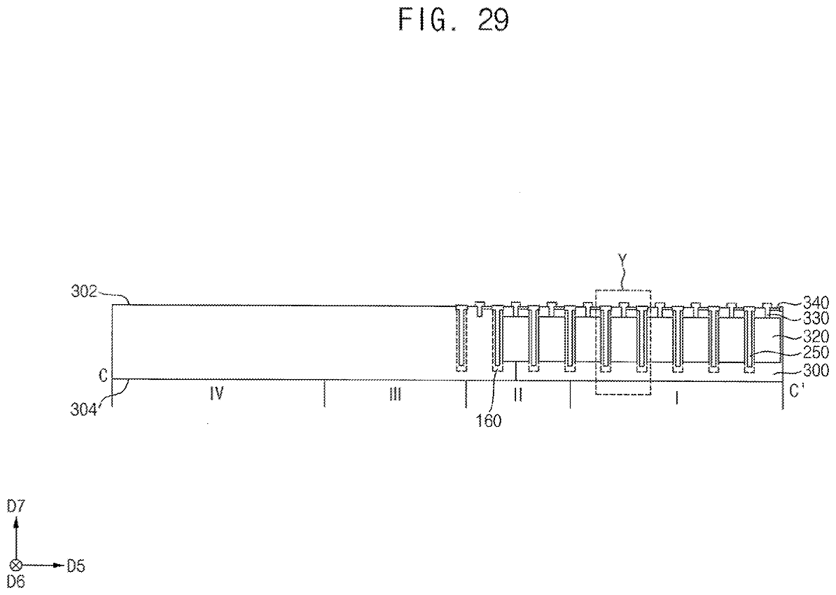

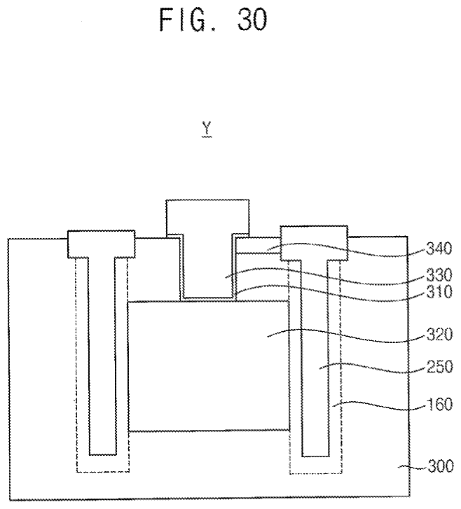

FIGS. 29 to 36 are cross-sectional views illustrating a method of manufacturing an image sensor in accordance with example embodiments. FIG. 30 is an enlarged cross-sectional view of region Y of FIG. 29. This method may include processes substantially the same as or similar to processes for forming the pixel division structure illustrated with reference to FIGS. 5 to 20, and thus repeated explanations thereof are omitted herein.

Referring to FIGS. 29 and 30, the pixel division structure 250, the impurity region 160 and the light sensing element 320 may be formed in the first substrate 300 including the first to fourth regions I, II, III and IV, and the TG 330 and the FD region 340 may be formed.

In example embodiments, p-type impurities, e.g., boron may be doped into a portion or an entire portion of the first substrate 300 to form a p-well.

The pixel division structure 250 and the impurity region 160 may be formed by processes substantially the same as or similar to those illustrated with reference to FIGS. 5 to 20. Thus, the pixel division structure 250 may be formed to extend from the first surface 302 in the seventh direction D7 downwardly in the first and second regions I and II of the first substrate 300, and the impurity region 160 including p-type impurities, e.g., boron may be formed at a portion of the first substrate 300 adjacent to the pixel division structure 250. An impurity concentration of the impurity region 160 may be higher than an impurity concentration of the p-well.

In example embodiments, the light sensing element 320 may be a portion of a PD. Thus, the light sensing element 320 may be formed by doping n-type impurities, e.g., phosphorus into the p-well in the first and second regions I and II of the first substrate 300.

In some embodiments, the pixel division structure 250 may be formed after forming the light sensing element 320.

The TG 330 may be formed by forming a fifth trench extending in the seventh direction D7 from the first surface 302 of the first substrate 300 downwardly, and filling the fifth trench and protruding from the trench upwardly using a conductive material.

The FD region 340 may be formed by doping n-type impurities, e.g., boron into a portion of the first substrate 300 adjacent to the first surface 302 and the TG 330.

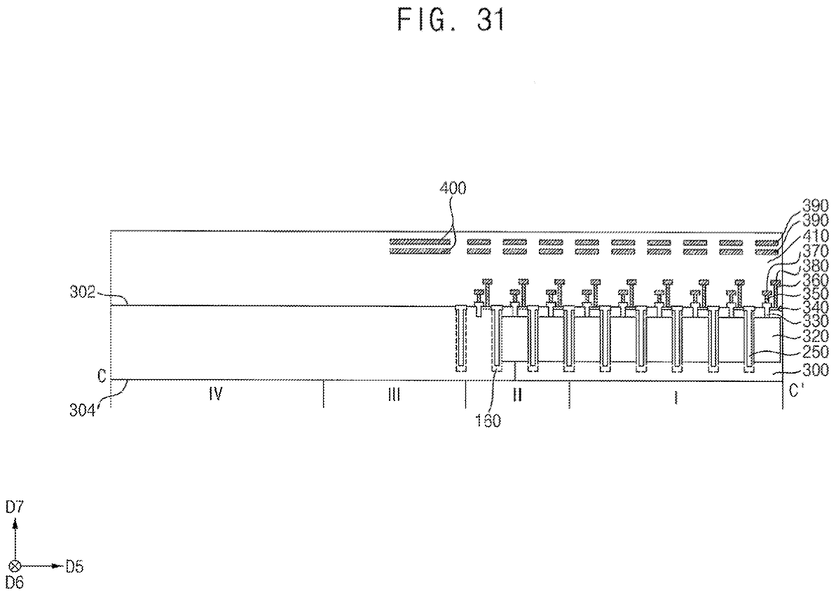

Referring to FIG. 31, a first insulating interlayer 410 containing first and second vias 350 and 360 and first to fourth wirings 370, 380, 390 and 400 may be formed on the first surface 302 of the first substrate 300.

In example embodiments, the first and second vias 350 and 360 and the first to fourth wirings 370, 380, 390 and 400 may be formed by a dual damascene process or a single damascene process.

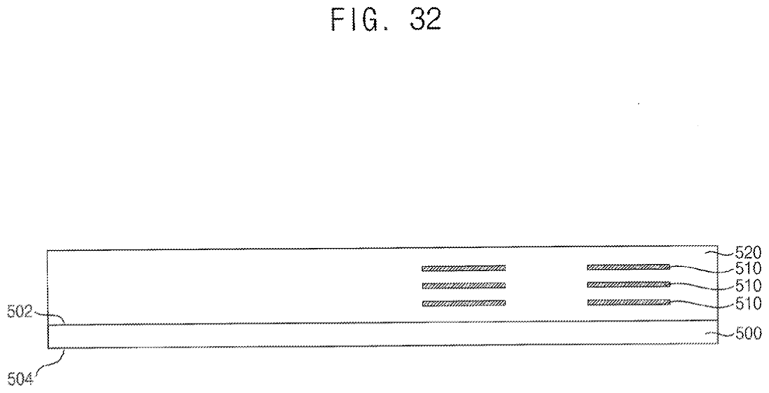

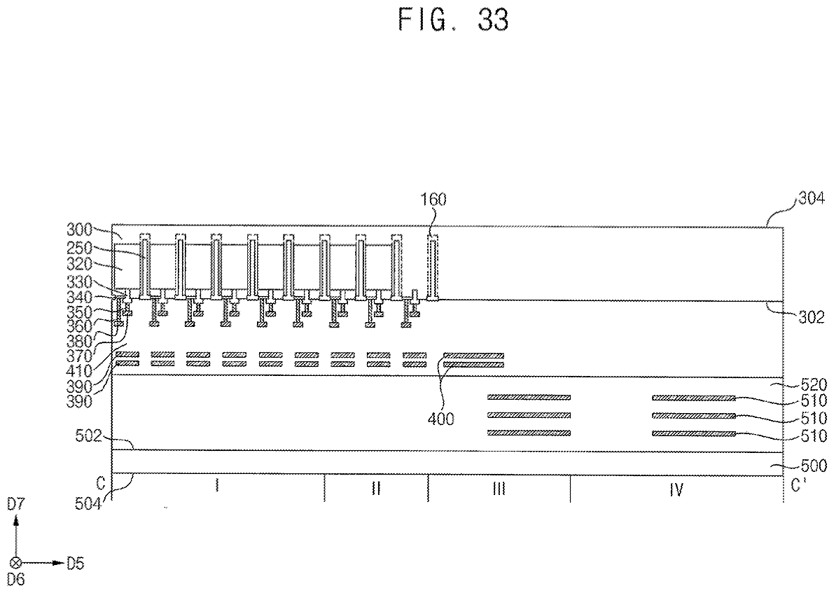

Referring to FIG. 32, a second insulating interlayer 520 containing a fifth wiring 510 and third vias connected to the fifth wiring 510 may be formed on a third surface 502 of a second substrate 500 including the third surface 502 and a fourth surface 504.

FIG. 32 shows the fifth wiring 510 is formed at third levels in the seventh direction D7, however, the disclosure may not be limited thereto. In example embodiments, the fifth wirings 510 and the third vias may be formed by a dual damascene process or a single damascene process.

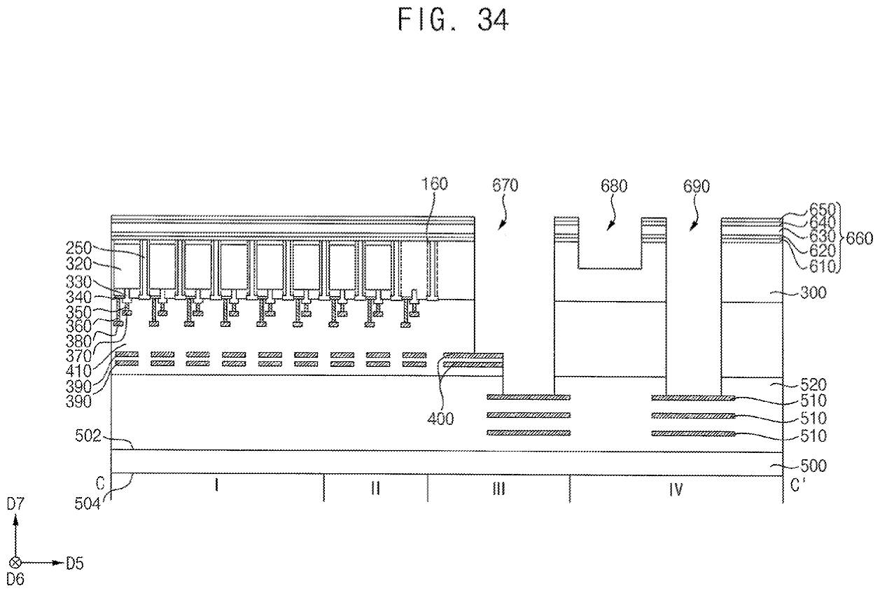

Referring to FIG. 33, the first insulating interlayer 410 on the first substrate 300 and the second insulating interlayer 520 on the second substrate 500 may be bonded with each other.

In example embodiments, the first and second insulating interlayers 410 and 520 may be bonded with each other through a bonding layer. Alternatively, the first and second insulating interlayers 410 and 520 may be directly bonded with each other. After bonding the first and second insulating interlayers 410 and 520, the bonded structure may be overturned so that the second surface 304 of the first substrate 300 may face upwardly.

As the first and second substrates 300 and 500 are bonded with each other, the fifth wirings 510 on the second substrate 500 may be disposed in the third and fourth regions III and IV.

Referring to FIG. 34, a portion of the first substrate 300 adjacent to the second surface 304 may be removed.

In example embodiments, the portion of the first substrate 300 adjacent to the second surface 304 may be removed by a polishing process, e.g., a grinding process, a CMP process, etc. Thus, the second filling pattern structure 225 included in the pixel division structure 250 may be partially removed, and the pixel division structure 250 may extend through the first substrate 300.

A lower planarization layer 660 may be formed on the second surface 304 of the first substrate 300.

In an example embodiment, the lower planarization layer 660 may include first to fifth layers 610, 620, 630, 640 and 650 sequentially stacked in the seventh direction D7.

The lower planarization layer 660, the first substrate 300, the first insulating interlayer 410 and an upper portion of the second insulating interlayer 520 in the third region III may be partially removed to form a first opening 670, the lower planarization layer 660 and an upper portion of the first substrate 300 in the fourth region IV may be removed to form a sixth trench 680, and the lower planarization layer 660, the first insulating interlayer 410 and an upper portion of the second insulating interlayer 520 in the fourth region IV may be removed to form a second opening 690.

The first opening 670 may expose the fourth wiring 400 in the first insulating interlayer 410 and the fifth wiring 510 in the second insulating interlayer 520, and the second opening 690 may expose the fifth wiring 510 in the second insulating interlayer 520.

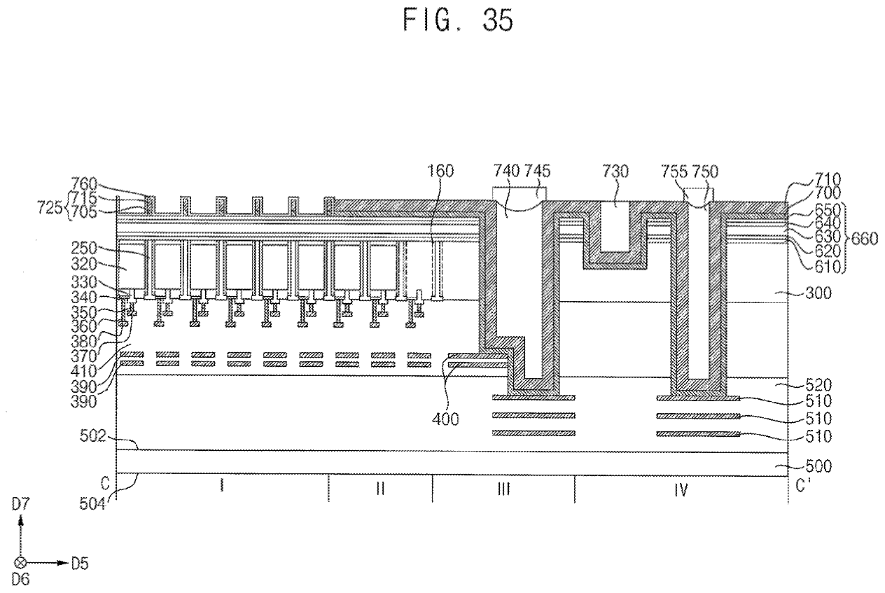

Referring to FIG. 35, a barrier layer and a first conductive layer may be sequentially formed on bottoms and sides of the first and second openings 670 and 690 and the sixth trench 680 and an upper surface of the lower planarization layer 660, a second conductive layer may be formed on the first conductive layer to fill the sixth trench 680, and an upper portion of the second conductive layer may be exposed until an upper surface of the first conductive layer is exposed.

Thus, a conductive pad 730 may be formed on the first conductive layer in the sixth trench 680 in the fourth region IV.

The planarization process may be performed by, e.g., a chemical mechanical polishing (CMP) process and/or an etch back process.

A fifth filling layer may be formed on the first conductive layer and the conductive pad 730 to fill the first and second openings 670 and 690, and an upper portion of the fifth filling layer may be planarized until an upper surface of the first conductive layer is exposed.

An additional etching process may be performed on the fifth filling layer so that a fifth filling pattern 740 may be formed on the first conductive layer in the first opening 670 in the third region III, and a sixth filling pattern 750 may be formed on the first conductive layer in the second opening 690 in the fourth region IV.

A capping layer may be formed on the fifth and sixth filling patterns 740 and 750 and the conductive pad 730 and patterned to form first and second capping patterns 745 and 755 on the fifth and sixth filling patterns 740 and 750, respectively.

Portions of the barrier layer and the first conductive layer in the first region I may be patterned to form first interference blocking pattern 705 and a second interference blocking pattern 715, respectively, and portions of the barrier layer and the first conductive layer in the second region II may remain as a barrier pattern 700 and a conductive pattern 710, respectively. The first and second interference blocking patterns 705 and 715 may form an interference blocking structure 725.

An upper surface of the lower planarization layer 660 in the first region I may be partially exposed.

Portions of the barrier pattern 700, the conductive pattern 710, the fifth filling pattern 740 and the first capping pattern 745 in the first opening 670 in the third region III may form a first through via structure, and portions of the barrier pattern 700, the conductive pattern 710, the sixth filling pattern 750 and the second capping pattern 755 in the second opening 690 in the fourth region IV may form a second through via structure.

A protection layer 760 may be formed on the lower planarization layer 660 and the interference blocking structure 725 in the first region I.

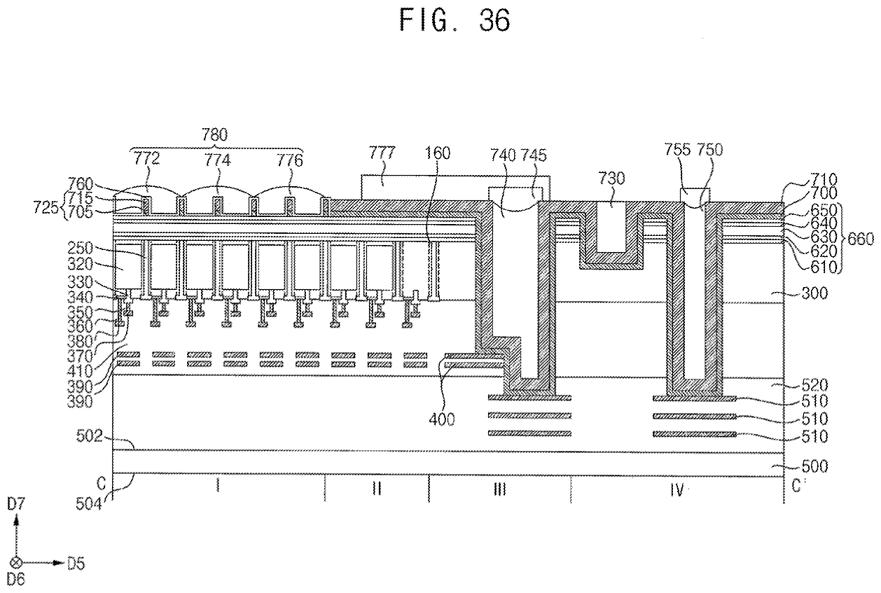

Referring to FIG. 36, a color filter array layer 780 including a first color filter 772, a second color filter 774 and a third color filter 776 may be formed on the protection layer 760 in the first region I, and a light blocking color filter layer 777 may be formed on the conductive pattern 710 and the first through via structure in the second and third regions II and III.

In example embodiments, each of the first color filter 772, the second color filter 774 and the third color filter 776 may be formed by depositing a color filter layer on the protection layer 760, the conductive pattern 710, the first and second capping patterns 745 and 755 and the conductive pad 730, e.g., through a spin coating process, and performing an exposure process and a developing process on the color filter layer.

The light blocking color filter layer 777 may be formed together with some of the color filters included in the color filter array layer 780, e.g., the second color filter 774.

In example embodiments, the first color filter 772, the second color filter 774 and the third color filter 776 may be a green filter G, a blue filter B and a red filter R, respectively. However, the disclosure may not be limited thereto.

Referring to FIGS. 27 and 28 again, an upper planarization layer 810 may be formed on the color filter array layer 780, the protection layer 760, the light blocking color filter layer 777, the conductive pad 730 and the second capping pattern 755 in the first to fourth regions I, II, III and IV, and a patterning process and a reflow process may be performed on the upper planarization layer 810 in the first region Ito form a microlens 800.

A transparent protection layer 820 may be formed on the microlens 800 and the upper planarization layer 810, and a portion of the transparent protection layer 820 overlapping the conductive pad 730 in the seventh direction D7 in the fourth region IV and a portion of the upper planarization layer 810 thereunder may be removed to form a third opening 830 exposing an upper surface of the conductive pad 730.

An upper wiring may be further formed to be electrically connected to the conductive pad 730 to complete the fabrication of the image sensor.

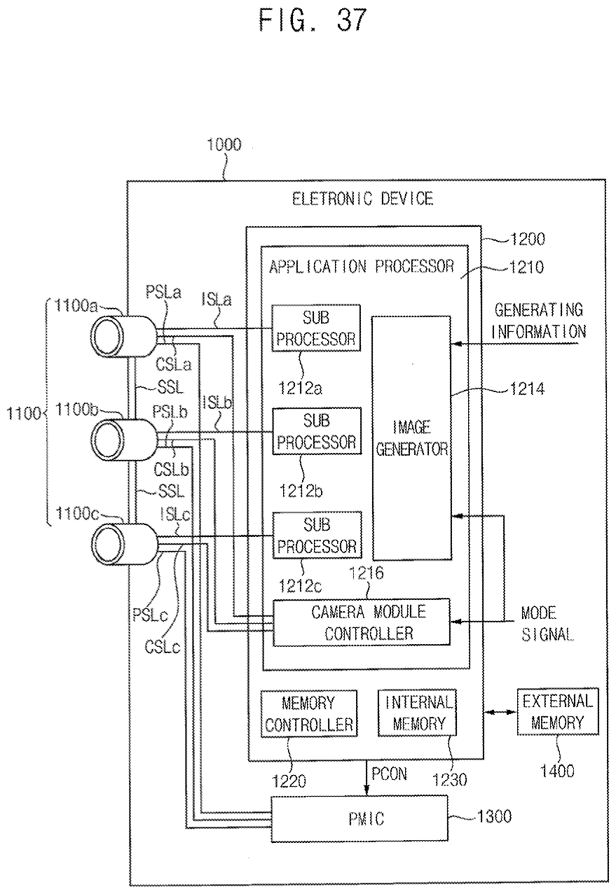

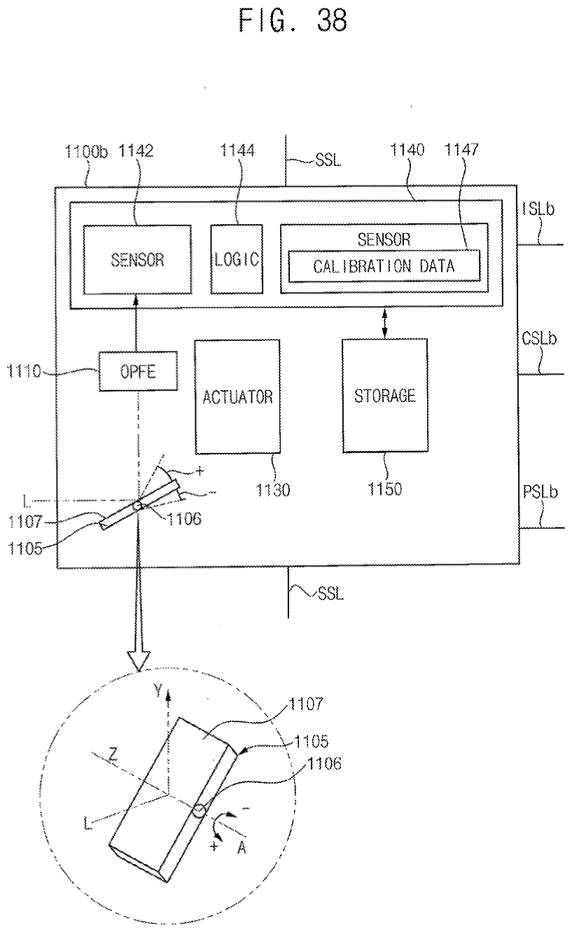

FIG. 37 is a block diagram illustrating an electronic device including an image sensor in accordance with example embodiments, and FIG. 38 is a block diagram illustrating a camera module included in the electronic device of FIG. 37.

The image sensor may be the image sensor illustrated with reference to FIGS. 27 and 28 including the pixel division structure illustrated with reference to FIGS. 1 to 4.

Referring to FIG. 37, an electronic device 1000 may include a camera module group 1100, an application processor 1200, a power management integrated circuit (PMIC) 1300 and an external memory 1400.

The camera module group 1100 may include a plurality of camera modules 1100a, 1100b and 1100c. FIG. 37 illustrates the three camera modules 1100a, 1100b and 1100c as an example, however, the disclosure may not be limited to a particular number of camera modules. According to example embodiments, the camera module group 1100 may include only two camera modules, or more than three camera modules.

Hereinafter, an example configuration of the camera module 1100b is described with reference to FIG. 38, however, the same descriptions may be applied to the other camera modules 1100a and 1100c.

Referring to FIG. 38, the camera module 1100b may include a prism 1105, an optical path folding element (OPFE) 1110, an actuator 1130, an image sensing device 1140 and a storage device 1150.

The prism 1105 may include a reflection surface 1107 that may change a path of a light L incident onto the prism 1105.

In example embodiments, the prism 1105 may change the path of the light L incident in a first direction X to a second direction Y perpendicular to the first direction X. In addition, the prism 1105 may rotate the reflection surface 1107 around a center axis 1106 in A direction and/or rotate the center axis 1106 in a B direction to align the path of the reflected light along the second direction Y. The OPFE 1110 may move in a third direction Z perpendicular to the first direction X and the second direction Y.

In example embodiments, a rotation angle of the prism 1105 may be equal to or less than about 15 degrees in the positive (+) A direction and equal to or more than about 15 degrees in the negative (−) A direction, but the disclosure may not be limited thereto.

In example embodiments, the prism 1105 may rotate within about 20 degrees, between about 10 degrees and about 20 degrees, or between about 15 degrees to about 20 degrees in the positive or negative B direction.

In example embodiments, the prism 1105 may move the reflection surface 1107 in the third direction Z that is in parallel with the center axis 1106.

The OPFE 1110 may include optical lenses that are divided into m groups where m is a positive integer. The m lens group may move in the second direction Y to change an optical zoom ratio of the camera module 1100b. For example, the optical zoom ratio may be changed in a range of 3K, 5K, and so on by moving the m lens group, when K is a basic optical zoom ratio of the camera module 1100b.

The actuator 1130 may move the OPFE 1110 or the optical lens to a specific position. For example, the actuator 1130 may adjust the position of the optical lens for accurate sensing such that an image sensor 1142 may be located at a position corresponding to a focal length of the optical lens.

The image sensing device 1140 may include the image sensor 1142, a control logic 1144 and a memory 1146. The image sensor 1142 may be substantially the same as or similar to that of FIG. 5 or FIG. 13, and may capture or sense an image using the light L provided through the optical lens. The control logic 1144 may control overall operations of the camera module 1100b. For example, the control logic 1144 may provide control signals through control signal line CSLb to control the operation of the camera module 1100b.

The memory 1146 may store information such as calibration data 1147 for the operation of the camera module 1100b. For example, the calibration data 1147 may include information for generation of image data based on the provided light L, such as information on the above-described rotation angle, a focal length, an optical axis, and so on. If the camera module 1100b is implemented as a multi-state camera having a variable focal length depending on the position of the optical lens, the calibration data 1147 may include multiple focal length values and auto-focusing values corresponding to the multiple states.

The storage device 1150 may store the image data sensed via the image sensor 1142. The storage device 1150 may be disposed at an outside of the image sensing device 1140, and may be stacked with a sensor chip including the image sensing device 1140. The storage device 1150 may be implemented with an electrically erasable programmable read-only memory (EEPROM), but the disclosure may not be limited thereto.

Referring to FIGS. 37 and 38, each of the camera modules 1100a, 1100b and 1100c may include the actuator 1130. Thus, the camera modules 1100a, 1100b and 1100c may include the same or different calibration data 1147 depending on the operations of the actuators 1130.

In example embodiments, one camera module 1100b may have a folded lens structure including the above-described prism 1105 and the OPFE 1110, and the other camera modules 1100a and 1100b may have a vertical structure without the prism 1105 and the OPFE 1110, however, the disclosure may not be limited thereto.

In example embodiments, one camera module 1100c may be a depth camera configured to measure distance information of an object using an infrared (IR) light. In this case, the application processor 1200 may merge the distance information provided from the depth camera 1100c and image data provided from the other camera modules 1100a and 1100b to generate a three-dimensional depth image.

In example embodiments, at least two camera modules, for example, the camera modules 1100a and 1100b among the camera modules 1100a, 1100b and 1100c may have different field of views, for example, through different optical lenses.

In example embodiments, the camera modules 1100a, 1100b and 1100c may be separated physically from each other. In other words, the camera modules 1100a, 1100b and 1100c may each include a dedicated image sensor 1142.

Referring to FIG. 37, the application processor 1200 may include an image processing device 1210, a memory controller 1220 and an internal memory 1230. The application processor 1200 may be separated from the camera modules 1100a, 1100b and 1100c. For example, the application processor 1200 may be implemented as one chip and the camera modules 1100a, 1100b and 1100c may implemented as another chip or other chips.

The image processing device 1210 may include a plurality of sub processors 1212a, 1212b and 1212c, an image generator 1214 and a camera module controller 1216.

The image data generated by the camera modules 1100a, 1100b and 1100c may be provided to the sub processors 1212a, 1212b and 1212c through distinct image signal lines ISLa, ISLb and ISLc, respectively. For example, image data generated from the camera module 1100a may be provided to the sub processor 1212a through the image signal line LSLa, image data generated from the camera module 1100b may be provided to the sub processor 1212b through the image signal line LSLb, and image data generated from the camera module 1100c may be provided to the sub processor 1212c through the image signal line LSLc. The transfer of the image data may be performed using a camera serial interface (CSI) based on the mobile industry processor interface (MIPI), however, the disclosure may not be limited thereto.

In example embodiments, one sub processor may be assigned commonly to two or more camera modules. In this case, a multiplexer may be used to transfer the image data selectively from one of the camera modules to the shared sub processor.

The image data from the sub processors 1212a, 1212b and 1212c may be provided to the image generator 1214. The image generator 1214 may generate an output image using the image data from the sub processors 1212a, 1212b and 1212c according to image generating information or a mode signal.

For example, the image generator 1214 may merge at least a portion of the image data from the camera modules 1100a, 1100b and 1100c having the different fields of view to generate the output image according to the image generating information or the mode signal. In addition, the image generator 1214 may select, as the output image, one of the image data from the camera modules 1100a, 1100b and 1100c according to the image generating information or the mode signal.

In example embodiments, the image generating information may include a zoom factor or a zoom signal. In example embodiments, the mode signal may be a signal based on a selection of a user.

If the image generating information is the zoom factor and the camera modules 1100a, 1100b and 1100c have the different field of views, the image generator 1214 may perform different operations depending on the zoom signal. For example, if the zoom signal is a first signal, the image generator 1214 may merge the image data from the different camera modules to generate the output image. If the zoom signal is a second signal different from the first signal, the image generator 1214 may select, as the output image, one of image data from the camera modules 1100a, 1100b and 1100c.

In example embodiments, the image generator 1214 may receive the image data of different exposure times from the camera modules 1100a, 1100b and 1100c. In this case, the image generator 1214 may perform high dynamic range (HDR) processing with respect to the image data from the camera modules 1100a, 1100b and 1100c to generate the output image having the increased dynamic range.

The camera module controller 1216 may provide control signals to the camera modules 1100a, 1100b and 1100c. The control signals generated by the camera module controller 1216 may be provided to the camera modules 1100a, 1100b and 1100c through the distinct control signal lines CSLa, CSLb and CSLc, respectively.

In example embodiments, one of the camera modules 1100a, 1100b and 1100c may be designated as a master camera according to the image generating information of the mode signal, and the other camera modules may be designated as slave cameras. These data may be included in the control signal, and may be provided to corresponding camera modules 1100a, 1100b and 1100c through the distinct control signal lines CSLa, CSLb and CSLc.

The camera module acting as the master camera may be changed according to the zoom factor or an operation mode signal. For example, if the camera module 1100a has the wider field of view than the camera module 1100b and the zoom factor indicates a lower zoom magnification, the camera module 1100b may be designated as the master camera. In contrast, if the zoom factor indicates a higher zoom magnification, the camera module 1100a may be designated as the master camera.

In example embodiments, the control signals provided from the camera module controller 1216 may include a synch enable signal. For example, if the camera module 1100b is the master camera and the camera modules 1100a and 1100c are the slave cameras, the camera module controller 1216 may provide the synch enable signal to the camera module 1100b. The camera module 1100b may generate a synch signal based on the provided synch enable signal and provide the synch signal to the camera modules 1100a and 1100c through a synch signal line SSL. As such, the camera modules 1100a, 1100b and 1100c may transfer the synchronized image data to the application processor 1200 based on the synch signal.

In example embodiments, the control signals provided from the camera module controller 1216 may include information on the operation mode. The camera modules 1100a, 1100b and 1100c may operate in a first operation mode or a second operation mode based on the information from the camera module controller 1216.

In the first operation mode, the camera modules 1100a, 1100b and 1100c may generate image signals with a first speed (e.g., a first frame rate) and encode the image signals with a second speed higher than the first speed (e.g., a second frame rate higher than the first frame rate) to transfer the encoded image signals to the application processor 1200. The second speed may be lower than thirty times the first speed. The application processor 1200 may store the encoded image signals in the internal memory 1230 or the external memory 1400. The application processor 1200 may read out and decode the encoded image signals to provide display data to a display device. For example, the sub processors 1212a, 1212b and 1212c may perform the decoding operation and the image generator 1214 may process the decoded image signals.

In the second operation mode, the camera modules 1100a, 1100b and 1100c may generate image signals with a third speed lower than the first speed (e.g., the third frame rate lower than the first frame rate) to transfer the generated image signals to the application processor 1200. In other words, the image signals that are not encoded may be provided to the application processor 1200. The application processor 1200 may process the received image signals or store the receive image signals in the internal memory 1230 or the external memory 1400.

The internal memory 1230 may be controlled by the memory controller 1220.

The PMIC 1300 may provide a power supply voltage to the camera modules 1100a, 1100b and 1100c, respectively. For example, the PMIC 1300 may provide, under control of the application processor 1200, a first power to the camera module 1100a through a power line PSLa, a second power to the camera module 1100b through a power line PSLb, and a third power to the camera module 1100c through a power line PSLc.

The PMIC 1300 may generate the power respectively corresponding to the camera modules 1100a, 1100b and 1100c and control power levels, in response to a power control signal PCON from the application processor 1200. The power control signal PCON may include information on the power depending on the operation modes of the camera modules 1100a, 1100b and 1100c. For example, the operation modes may include a low power mode in which the camera modules 1100a, 1100b and 1100c operate in low powers. The power levels of the camera modules 1100a, 1100b and 1100c may be the same as or different from each other. In addition, the power levels may be changed dynamically or adaptively.

Although example embodiments have been described above, those skilled in the art will readily appreciate that many modifications are possible in the example embodiments without materially departing from the novel teachings and advantages of the disclosure. Each of the embodiments is not excluded from being associated with one or more features of another example or another embodiment also provided herein or not provided herein but consistent with the disclosure. For example, even if matters described in a pixel division structure in an embodiment are not described in a pixel division structure in another embodiment, the matters may be understood as being related to or combined with the pixel division structure in the other embodiment, unless otherwise mentioned in descriptions thereof. In addition, it should be understood that all descriptions of principles, aspects, examples, and specific embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof.

What is claimed is:

1. An image sensor comprising:
a pixel division structure extending through a substrate in a vertical direction, the vertical direction being substantially perpendicular to an upper surface of the substrate, the pixel division structure defining unit pixel regions in which unit pixels are respectively formed;
a light sensing element in each of the unit pixel regions;
a color filter array layer on the substrate, the color filter array layer comprising color filters; and
a microlens on the color filter array layer,
wherein the pixel division structure comprises:
a core; and
a lateral pattern structure on a sidewall of the core, and
wherein the core comprises:
a first filling pattern comprising polysilicon doped with p-type impurities or n-type impurities at a first impurity concentration; and
a second filling pattern in a space formed by the first filling pattern, a sidewall of the second filling pattern being covered by the first filling pattern, and the second filling pattern comprising polysilicon doped with p-type impurities or n-type impurities at a second impurity concentration different from the first impurity concentration.

2. The image sensor of claim 1, wherein the first impurity concentration is greater than the second impurity concentration.

3. The image sensor of claim 1, wherein the second impurity concentration is greater than the first impurity concentration.

4. The image sensor of claim 1, wherein the p-type impurities or n-type impurities of the first filling pattern are substantially the same as the p-type impurities or n-type impurities of the second filling pattern.

5. The image sensor of claim 1, wherein a width of the second filling pattern gradually increases in the vertical direction from a top of the second filling pattern toward a bottom of the second filling pattern.

6. The image sensor of claim 5, wherein a thickness of a portion of the first filling pattern contacting the second filling pattern gradually decreases in the vertical direction from a top of the first filling pattern toward a bottom of the first filling pattern.

7. The image sensor of claim 1, wherein the core comprises a first portion comprising only the first filling pattern and a second portion comprising both the first filling pattern and the second filling pattern, and
wherein a minimum width of a portion of the pixel division structure corresponding to the second portion of the core is greater than a minimum width of a portion of the pixel division structure corresponding to the first portion of the core.

8. The image sensor of claim 7, wherein the pixel division structure has a lattice shape in a plan view,
wherein the unit pixel regions are spaced apart from each other by the pixel division structure in a first direction and a second direction substantially parallel to an upper surface of the substrate, and
wherein the second portion of the core is disposed among four unit pixel regions adjacent to one another.

9. The image sensor of claim 1, wherein at least one of the first filling pattern and the second filling pattern comprises carbon or oxygen.

10. The image sensor of claim 1, wherein the lateral pattern structure comprises a first lateral pattern and a second lateral pattern stacked from the sidewall of the core, and
wherein the first lateral pattern and the second lateral pattern comprise a nitride and an oxide, respectively.

11. The image sensor of claim 10, wherein the first lateral pattern comprises silicon nitride, and
wherein the pixel division structure further comprises a seed pattern between the first lateral pattern and the first filling pattern.

12. The image sensor of claim 11, wherein the seed pattern comprises silicon carbonitride.

13. The image sensor of claim 1, wherein the lateral pattern structure comprises a single layer comprising an oxide.

14. The image sensor of claim 1, wherein a center portion of a lower surface of the core protrudes in an upward direction.

15. The image sensor of claim 1, wherein the core and the lateral pattern structure form a first filling pattern structure, and
wherein the pixel division structure further comprises a second filling pattern structure under the first filling pattern structure.

16. (canceled)

17. (canceled)

18. An image sensor comprising:
a pixel division structure extending through a substrate in a vertical direction, the vertical direction being substantially perpendicular to an upper surface of the substrate, the pixel division structure defining unit pixel regions in which unit pixels are respectively formed;
a light sensing element in each of the unit pixel regions;
a color filter array layer on the substrate, the color filter array layer comprising color filters; and
a microlens on the color filter array layer,
wherein the pixel division structure comprises:
a core; and
a lateral pattern structure on a sidewall of the core, and
wherein the core comprises:
a first filling pattern comprising a conductive material; and
a second filling pattern in a space formed by the first filling pattern, a sidewall of the second filling pattern being covered by the first filling pattern, and
wherein a thickness of a portion of the first filling pattern contacting the second filling pattern gradually decreases in the vertical direction from a top of the first filling pattern toward a bottom of the first filling pattern.

19. The image sensor of claim 18, wherein a width of the second filling pattern gradually increases in the vertical direction from a top of the second filling pattern toward a bottom of the second filling pattern.

20-28. (canceled)

29. An image sensor comprising:
a pixel division structure extending through a substrate in a vertical direction, the vertical direction being substantially perpendicular to an upper surface of the substrate, the pixel division structure defining unit pixel regions in which unit pixels are respectively formed;
a light sensing element in each of the unit pixel regions;
a color filter array layer on the substrate, the color filter array layer comprising color filters; and
a microlens on the color filter array layer,
wherein the pixel division structure comprises:
a core; and
a lateral pattern structure on a sidewall of the core,
wherein the core comprises a first portion and a second portion,
wherein the first portion of the core comprises only a first filling pattern comprising a conductive material, and
wherein the second portion of the core comprises the first filling pattern and a second filling pattern, a sidewall of the second filling pattern being covered by the first filling pattern.

30. The image sensor of claim 29, wherein a minimum width of a portion of the pixel division structure corresponding to the second portion of the core is greater than a minimum width of a portion of the pixel division structure corresponding to the first portion of the core.

31. The image sensor of claim 29, wherein the first filling pattern comprises polysilicon doped with p-type impurities or n-type impurities at a first impurity concentration, and
wherein the second filling pattern comprises polysilicon doped with p-type impurities or n-type impurities at a second impurity concentration different from the first impurity concentration.

32-70. (canceled)
